(19) United States
(12) Patent Application Publication
(10) Pub. No.: US 2026/0107527 A1
(43) Pub. Date: Apr. 16, 2026

(54) SEMICONDUCTOR DEVICE AND FORMATION METHOD THEREOF

(71) Applicant: TAIWAN SEMICONDUCTOR MANUFACTURING COMPANY, LTD., Hsinchu (TW)

(72) Inventors: Ming-Heng TSAI, Taipei City (TW); Ta-Chun LIN, Hsinchu (TW)

(73) Assignee: TAIWAN SEMICONDUCTOR MANUFACTURING COMPANY, LTD., Hsinchu (TW)

(21) Appl. No.: 18/912,354

(22) Filed: Oct. 10, 2024

(51) Int. Cl. H01L 29/06; H01L 27/092; H01L 29/423; H01L 29/66; H01L 29/775; H01L 29/78; H01L 29/786

(52) U.S. Cl. CPC H10D 62/121; H10D 30/014; H10D 30/43; H10D 30/6735; H10D 30/6757; H10D 64/017; H10D 64/018; H10D 84/85; H10D 30/024; H10D 30/62

(57) ABSTRACT

A semiconductor device includes a substrate comprising first and second active region patterns, first semiconductor layers extending in a first direction above the first active region pattern and spaced apart in a second direction perpendicular to the first direction, second semiconductor layers extending in the first direction above the second active region pattern and spaced apart in the second direction, a first inner spacer between the two adjacent first semiconductor layers and a second inner spacer between the two adjacent second semiconductor layers. The first active region pattern does not overlap the second active region pattern. The first inner spacer has a first thickness along the first direction. The second inner spacer has a second thickness along the first direction, and the first thickness is different from the second thickness.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a simplified schematic top view of a first cell layout diagram of a semiconductor device in accordance with some embodiments of the present disclosure.

FIGS. 2A and 2B are cross-sectional views along lines A-A and B-B of FIG. 1, respectively.

FIGS. 3A, 3B and 3C show simplified schematic top views of a second cell layout diagram, a third cell layout diagram and a fourth cell layout diagram of semiconductor devices in accordance with some embodiments of the present disclosure.

FIGS. 4 through 7, 8A, 18A, 19A, 20A, 21A and 22A illustrate reference cross-section that extends through a gate region along a longitudinal axis of the gate region of the semiconductor device 100.

FIGS. 8B, 9B, 10B, 11B, 12B, 13B, 14B, 15B, 16B, 17B, 18B, 19B, 20B, 21B, 22B and 23 illustrate reference cross-section that extends through a fin along a longitudinal axis of the fin.

FIGS. 9A, 10A, 11A, 12A, 13A, 14A, 15A, 16A, 17A and 18C illustrate reference cross-section that extends through source/drain regions along the longitudinal direction of the gate region.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 230 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. In this disclosure, a source/drain refers to a source and/or a drain. It is noted that in the present disclosure, a source and a drain are interchangeably used and the structures thereof are substantially the same.

The gate all around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Active area patterns are commonly referred to as “OD patterns,” i.e., oxide-definition (OD) patterns. The OD patterns are configured to define active devices in a chip. Examples of active devices include, but are not limited to, transistors and diodes. Examples of transistors include, but are not limited to, metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), or FinFETs, planar MOS transistors with raised source/drains. The OD patterns are isolated from each other by the isolation structures.

The OD patterns with small width, which can be referred to as small “OD width (ODW),” may have poor epitaxial source/drain structure healthiness and not capable for convex junction push, at cost of direct current (DC) loss by junction overlap.

Embodiments of the present disclosure provide a semiconductor device including a first OD pattern with a small ODW in which inner spacers are small such that a first metal gate crossing the first OD pattern can have a large critical dimension (CD) in between nanostructures. Therefore, Short channel effect (SCE) and drain-induced barrier lowering (DIBL) of the semiconductor device can be effectively controlled. Junction between a source/drain region and a nanosheet channel region can overlap even without additional process for convex push or junction push, and hence better on-current (Ion) can be achieved. The semiconductor device can be applied to low threshold power (P_{sb}) device with reduced SCE or combined with OD jog for Design Technology Co-Optimization (DTCO).

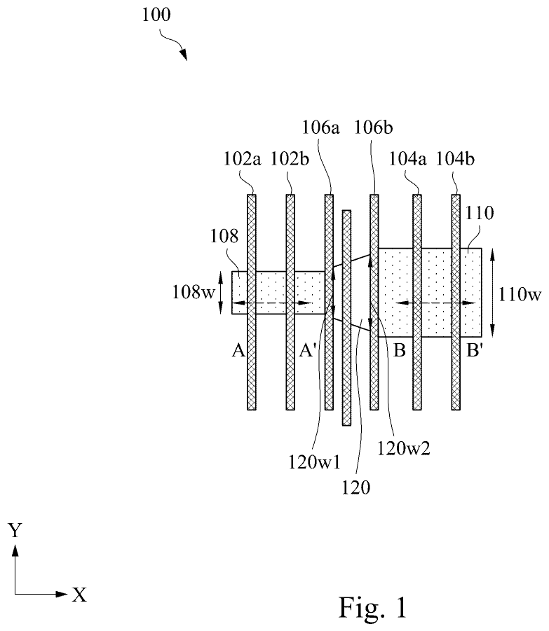

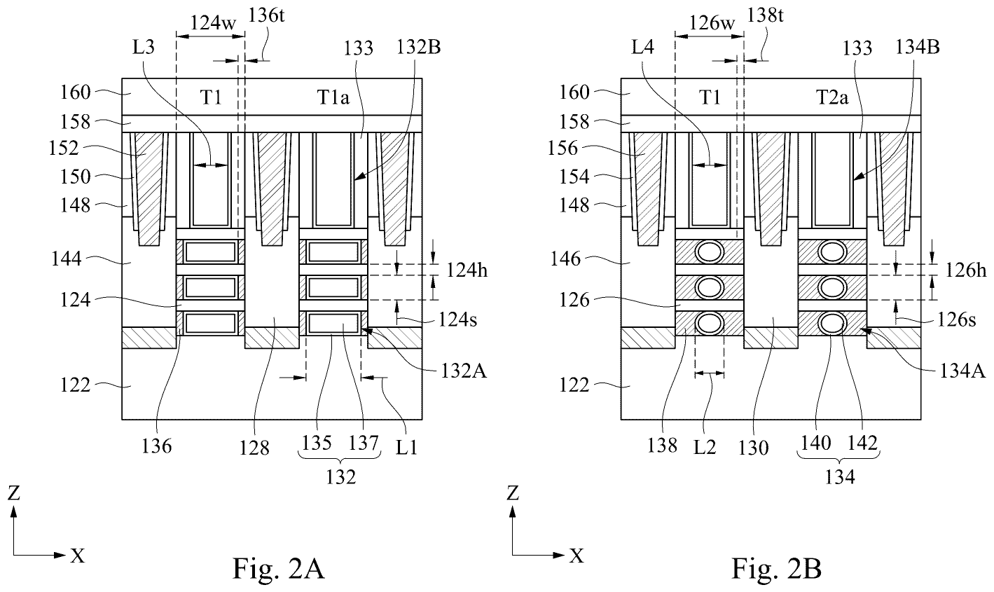

FIG. 1 is a simplified schematic top view of a first cell layout diagram of a semiconductor device 100 in accordance with some embodiments of the present disclosure. FIG. 1 is a top view (plane view) of a semiconductor device in accordance with some embodiments. FIG. 1 further depicts an X direction and a Y direction perpendicular to the X direction. The X direction being depicted as horizontal with respect to the page and the Y direction being depicted as vertical are a non-limiting example for the purpose of illustration. FIGS. 2A and 2B are cross-sectional views along lines A-A and B-B of FIG. 1, respectively. In greater detail, FIGS. 2A and 2B are cross-sectional views along the X-direction. The first cell layout can include a plurality of first conductive patterns 102a, 102b, a plurality of second conductive patterns 104a, 104b, a first active region pattern 108, a second active region pattern 110, continuous poly on diffusion edge (CPODE) patterns 106a, 106b. The CPODE patterns 106a, 106b are strip structures which can be formed by forming a trench by removing a dummy gate structure and a portion of a substrate under the dummy structure using a photolithography process and an etch process, and filling the trench with a dielectric layer or an insulating layer. During the photolithography process, the dummy gate structure corresponding to the CPODE pattern is exposed while the other gate structures or dummy gate structures are covered by a mask layer. In some embodiments, the trench separates the two abutted active regions. In some embodiments, the trench is between two abutted standard cells. The trench extends through at least the abutted two well regions of the two abutted active regions, i.e., a bottom surface of the trench is below a bottom surface of the abutted two well regions. The first cell layout can include a width of 1CPP transition with two CPODEs between the first active region pattern 108 and the second active region pattern 110. In some embodiments, CPP is an abbreviation of the term ‘contact poly pitch.’ In some embodiments, CPP is a minimum center-to-center space (distance) between gates of adjacent transistors of one or more cell structures that are coupled to a single Through Silicon Via (TSV) structure. In some other embodiments, the semiconductor device 100 can include two or more CPP transition with two or more CPODEs. In some embodiments, a distance between the first active region pattern 108 and the second active region pattern 110 equals to a minimum distance between a center of the first gate structure 132 and a center of the second gate structure 134. In some other embodiments, the distance between the first active region pattern 108 and the second active region pattern 110 is less than the minimum distance between the center of the first gate structure 132 and the center of the second gate structure 134.

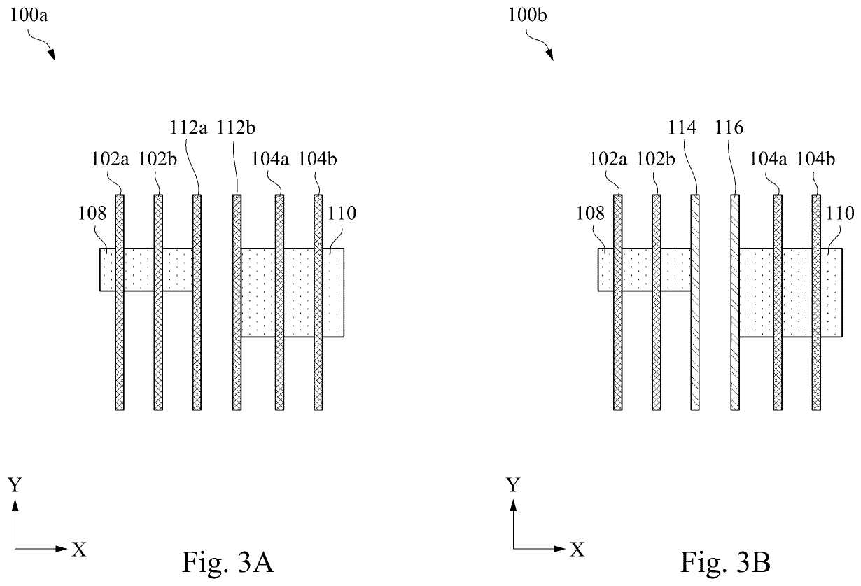

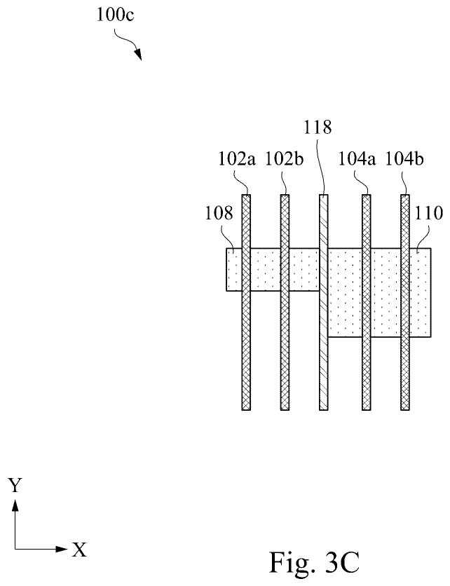

FIGS. 3A, 3B and 3C show simplified schematic top views of a second cell layout diagram, a third cell layout diagram and a fourth cell layout diagram of semiconductor devices 100a, 100b, 100c in accordance with some embodiments of the present disclosure. FIGS. 3A, 3B and 3C are top views (plane views) of a semiconductor devices 100a, 100b, 100c in accordance with some embodiments. The second cell layout is similar to the first cell layout with respect to FIG. 1, except for the second cell layout including poly on diffusion edges (PODEs) but not the 1CPP. The PODE patterns are strip structures which can be formed over edges of the OD patterns. For example, PODE patterns 112a, 112b are formed over edges of the first active region pattern 108 and the second active region pattern 110. The PODE patterns 112a, 112b are used for preventing leakage between neighboring devices (cells). The PODE patterns 112a, 112b help achieve improved device performance and better poly profile control. In at least one embodiment, the PODE patterns do not constitute any functional feature of one or more active devices formed in the corresponding OD pattern.

The third cell layout is similar to the first cell layout with respect to FIG. 1, except for the third cell layout including the PODE pattern 114 and a CPODE pattern 116 but not the 1CPP. The fourth cell layout is similar to the first cell layout with respect to FIG. 1, except for including 0CPP but not the 1CPP. The fourth cell layout can include continuous poly on diffusion edge (CPODE) pattern 118 on edges of the first active region pattern 108 and the second active region pattern 110. In some embodiments, the semiconductor device 100 can include at least two transistors T1, T1a in the first active region pattern 108 and at least two transistors T2, T2a in the second active region pattern 110.

Referring back to FIG. 1, in some embodiments, the first active region pattern 108 has a first width 108w along the Y-direction, and the second active region pattern 110 has a second width 110w along the Y-direction different form the first width 108w. For example, the first width 108w is smaller than the second width 110w. In some embodiments, the first width 108w is in a range from about 5 nm to about 10 nm, and the second width 110w is in a range from about 15 nm to about 50 nm. In some embodiments, the semiconductor device 100 can include a jog portion 120 or other suitable nominal portion between the first active region pattern 108 and the second active region pattern 110. For example, the jog portion 120 can be on one side of the CPODE 106a and on one side of the CPODE 106b. In some embodiments, the jog portion 120 can include a first width 120w1 abutting the side of the CPODE 106a and a second width 120w2 abutting the side of the CPODE 106b different from the first width 120w1. In some embodiments, a width difference (120w2-120w1) of the first width 120w1 and the second width 120w2 can be in a range from about 2 nm to about 30 nm. That is, a size of the jog portion 120 can be in a range from about 2 nm to about 30 nm. In some embodiments, the jog portion 120 has a trapezoid profile when viewed from a top view.

Reference is made to FIGS. 1, 2A and 2B. The semiconductor device 100 may include a substrate (see FIGS. 2A and 2B) 122. The substrate 122 may be made of silicon or other semiconductor materials. Alternatively or additionally, the substrate 122 may include other elementary semiconductor materials such as germanium. In some embodiments, the substrate 122 is made of a compound semiconductor such as silicon carbide (SiC), gallium arsenic (GaAs), indium arsenide (InAs), or indium phosphide (InP). In some embodiments, the substrate 122 is made of an alloy semiconductor such as silicon germanium (SiGe), silicon germanium carbide (SiGeC), gallium arsenic phosphide (GaAsP), or gallium indium phosphide (GaInP). In some embodiments, the substrate 122 includes an epitaxial layer. For example, the substrate 122 has an epitaxial layer overlying a bulk semiconductor.

In some embodiments, the first active region pattern 108 includes a plurality of semiconductor layers 124 having a lengthwise direction extending along the X-direction. In some embodiments, the semiconductor layers 124 can also be referred to as semiconductor channel layers. In some embodiments, the second active region pattern 110 includes a plurality of semiconductor layers 126 having a lengthwise direction extending along the X-direction and spaced apart in a Z-direction perpendicular to the X and Y directions. In some embodiments, the semiconductor layers 126 can also be referred to as semiconductor channel layers. Although in FIGS. 2A and 2B, sheet numbers of the semiconductor layers 124, 126 are the same, the present disclosure is not limited thereto. For example, in some other embodiments, a number (or sheet number) of the semiconductor layers 124 and a number of the semiconductor layers 126 can be different.

Although in FIGS. 2A and 2B, a sheet height 124h of the semiconductor layers 124 and a sheet height 126h of the second semiconductor layers 126 are the same, the present disclosure is not limited thereto. For example, in some other embodiments, the sheet height 124h of the first semiconductor layers 124 and the sheet height 126h of the second semiconductor layers 126 can be different from each other. The sheet height difference (124h-126h) can be in a range from about 0.5 nm to about 5 nm.

Although in FIGS. 2A and 2B, sheet space between each of the first semiconductor layers 124 and sheet space between each of the second semiconductor layers 126 are the same, the present disclosure is not limited thereto. For example, in some other embodiments, the sheet space between each of the first semiconductor layers 124 and the sheet space between each of the semiconductor layers 126 can be different from each other. The sheet space difference (124s-126s) can be in a range from about 0.5 nm to about 5 nm.

In some embodiments, the first active region pattern 108 is different from the second active region pattern 110 at least in conductivity type. For example, the first active region pattern 108 can be for forming p-type devices, such as PMOS transistors, e.g., p-type gate-all-around FETs (GAA-FETs), and the second active region pattern 110 can be for forming n-type devices, such as NMOS transistors, e.g., n-type GAA-FETs. The p-type devices may include a metal gate including a first p-type work function metal layer. The n-type device may include a metal gate including a n-type work function metal layer. In some embodiments where the transistors T1, T1a are p-type transistors such as p-type MOS (PMOS) and the transistors T2, T2a are n-type transistors such as n-type MOS (NMOS), the sheet heights of the NMOS transistor and the PMOS transistor can be different from each other, and the sheet spaces of the NMOS transistor and the PMOS transistor can be different from each other.

As shown in the cross-sectional views of FIGS. 2A and 2B, the semiconductor layers 124 are stacked along a vertical direction, and the semiconductor layers 126 are stacked along the vertical direction. In some embodiments, the semiconductor layers 124, 126 may be made of suitable semiconductor materials, such as Si, SiGe, Group III-V compounds, Group II-VI compounds, or the like. In some other embodiments, the semiconductor layers 124 and the semiconductor layers 126 can be different from ach other.

As shown in the cross-sectional view of FIGS. 2A and 2B, the semiconductor device 100 includes a plurality of source/drain epitaxy structures 128 and 130. The source/drain epitaxy structures 128 may be formed on opposites sides of the semiconductor layers 124 and on opposite sides of first and second gate structures 132, 134. The source/drain epitaxy structures 128, 130 may be formed on opposites sides of the semiconductor layers 124 and on opposite sides of the first and second gate structures 132, 134.

The semiconductor device 100 further includes first inner spacers 136 between two adjacent semiconductor layers 124 of the first active region pattern 108 and second inner spacers 138 between two adjacent semiconductor layers 126 of the second active region pattern 110. In some embodiments, the first and second inner spacers 136, 138 can include a dielectric material such as SiN, SiO₂, SiON, SiCN, SiCON, SiCO, high-k dielectric material (e.g., HfO, AlO, the like), or multiple layer composite thereof.

In some embodiments, the semiconductor layers 124, 126 can include a width 124w in a range from about 5 nm to about 80 nm. In some embodiments, the first inner spacers 136 and the second inner spacers 138 can include first and second thicknesses 136t, 138t, respectively, in a range from about 2 nm to about 10 nm. In some embodiments where the first width 108w of the first active region pattern 108 is about 5 nm to about 10 nm and the second width 110w of the second active region pattern 110 is about 15 nm to about 50 nm, the thickness difference (138t-136t) can be in a range from about 1 nm to about 2 nm.

In some embodiments, epitaxial source/drain regions 144 can be formed on opposite sides of the semiconductor layers 124, and epitaxial source/drain regions 146 can be formed on opposite sides of the semiconductor layers 126. An interfacial dielectric (ILD) layer 148 can be formed surrounding the first gate structure 132 and the second gate structure 134. In some embodiments, an insulating liner layer 150 and a conductive material layer 152 over the insulating liner layer 150 can be formed over the epitaxial source/drain regions 144. In some embodiments, an insulating liner layer 154 and a conductive material layer 156 over the insulating liner layer 154 can be formed over the epitaxial source/drain regions 146. In some embodiments, a second ILD layer 160 is formed over the first ILD layer 148, the first gate structure 132 and the second gate structure 134.

As shown in the cross-sectional view of FIGS. 2A and 2B, the first gate structure 132 includes a gate dielectric 135 and a gate electrode 137 over the gate dielectric 135. The second gate structure 134 includes a gate dielectric 140 and a gate electrode 142 over the gate dielectric 140. In some embodiments, the gate dielectrics 135, 140 include one layer of high-k dielectric. In some other embodiments, the gate dielectrics 135, 140 include multi-layer structure, such as an interfacial layer and a high-k dielectric material. Examples of high-k dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-k dielectric materials, and/or combinations thereof. Examples of interfacial layer include silicon oxide (SiO₂), silicon nitride (SiN), silicon oxynitride (SiON), hBN, aluminum oxide (Al₂O₃), other suitable dielectric material, and/or combinations thereof. In some embodiments where the first transistors T1, T1a are PMOS and the second transistors T2, T2a are NMOS, the interfacial layers of the first transistors T1, T1a and the interfacial layers of the second transistors T2, T2 can include different materials, and the high-k dielectric material of the first transistors T1, T1a and the high-k dielectric material of the second transistors T2, T2 can include different materials.

In some other embodiments, the interfacial layer of the first gate structure 132 and the interfacial layer of the second gate structure 134 can have different thicknesses. In some embodiments where the first transistors T1, T1a are PMOS and the second transistors T2, T2a are NMOS, although in FIGS. 2A and 2B, the gate dielectric layer 137 of the first gate structure 132 and the gate dielectrics 140 of the second gate structure 134 are illustrated as including the same thickness, in some other embodiments, the gate dielectric layer 137 of the first gate structure 132 and the gate dielectrics 140 of the second gate structure 134 can have different thicknesses.

In some embodiments, the gate electrodes 137, 142 include a conductive material and may be selected from a group comprising of polycrystalline-silicon (poly-Si), poly-crystalline silicon-germanium (poly-SiGe), metallic nitrides, metallic silicides, metallic oxides, and metals. Examples of metallic nitrides include tungsten nitride, molybdenum nitride, titanium nitride, and tantalum nitride, or their combinations. Examples of metallic silicide include tungsten silicide, titanium silicide, cobalt silicide, nickel silicide, platinum silicide, erbium silicide, or their combinations. Examples of metallic oxides include ruthenium oxide, indium tin oxide, or their combinations. Examples of metals include tantalum, tungsten, titanium, aluminum, copper, molybdenum, nickel, platinum, etc.

The first gate structure 132 can include inner gates 132A between two adjacent semiconductor layers 124 and an outer gate 132B above the topmost one of the semiconductor layers 124. The second gate structure 134 can include inner gates 134A between two adjacent semiconductor layers 126 and an outer gate 132B above the semiconductor layers 124. The outer gate 132B can adjoin gate spacers 133. In some embodiments, the inner gates 132A and 134A can include a gate length L1 in a range from about 5 nm to about 100 nm. In some embodiments where the first width 108w of the first active region pattern 108 is about 5 nm to about 10 nm and the second width 110w of the second active region pattern 110 is about 15 nm to about 50 nm, a length difference (L1−2) can be in a range from about 1 nm to about 4 nm. In the first active region pattern 108, the length L1 of the inner gates 132A is greater than a length L3 of the outer gate 132B. In some embodiments, the gate spacer 133 can be wider than the first inner spacers 136 in the X direction. In the second active region pattern 110, the length L2 of the inner gates 134A is greater than a length L4 of the outer gate 134B. In some embodiments, the gate spacer 133 can be thinner than the second inner spacers 138 in the X direction.

The semiconductor device 100 including the first active region pattern 108 with a small first width 108w along the Y-direction in which the first inner spacers 136 are small such that the first gate structure 132 crossing the first active region pattern 108 can have a large critical dimension (CD) in between semiconductor layers 124. Therefore, Short channel effect (SCE) and drain-induced barrier lowering (DIBL) of the semiconductor device 100 can be effectively controlled. Junction between an epitaxial source/drain region 144 and a nanosheet channel region (i.e., the semiconductor layers 124 can overlap even without additional process for convex push or junction push, and hence better on-current (Ion) can be achieved. The semiconductor device 100 can be applied to low threshold power (P_{sb}) device with reduced SCE or combined with OD jog for Design Technology Co-Optimization (DTCO).

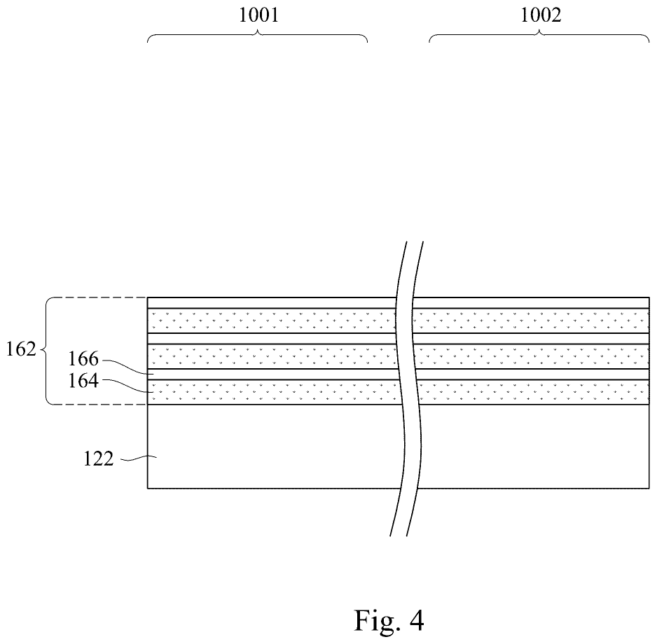

Some embodiments discussed herein are discussed in the context of GAA-FETs formed using a gate-last process. In other embodiments, a gate-first process may be used. Also, some embodiments contemplate aspects used in planar devices, such as planar FETs or in fin field-effect transistors (FinFETs). FIGS. 4-23 are cross-sectional views of the semiconductor device 100, at various fabrication stages according to some embodiments.

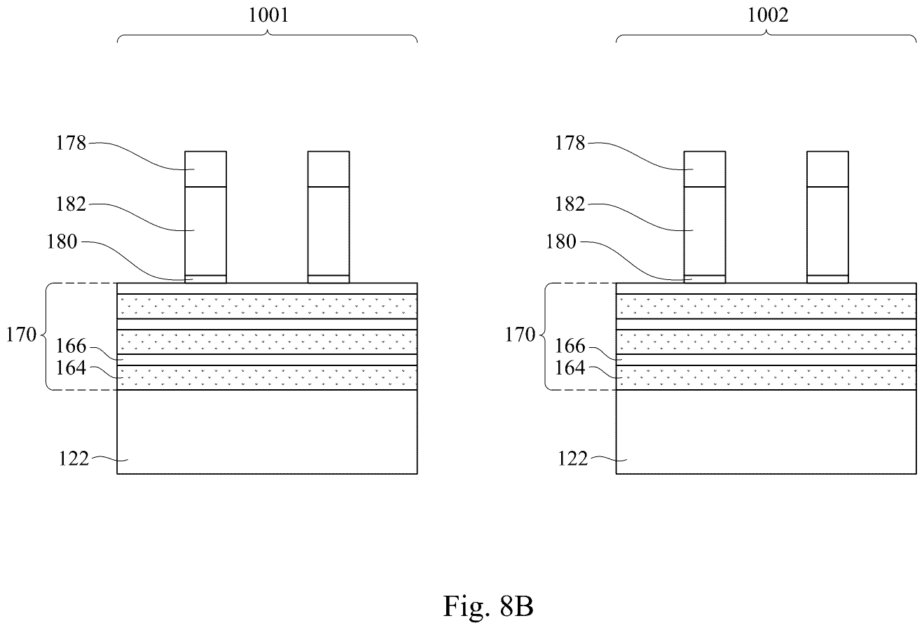

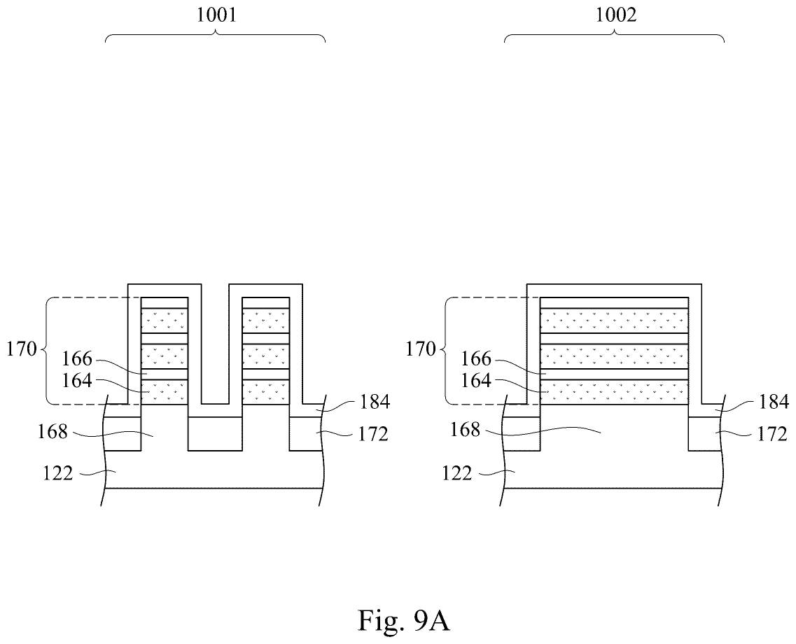

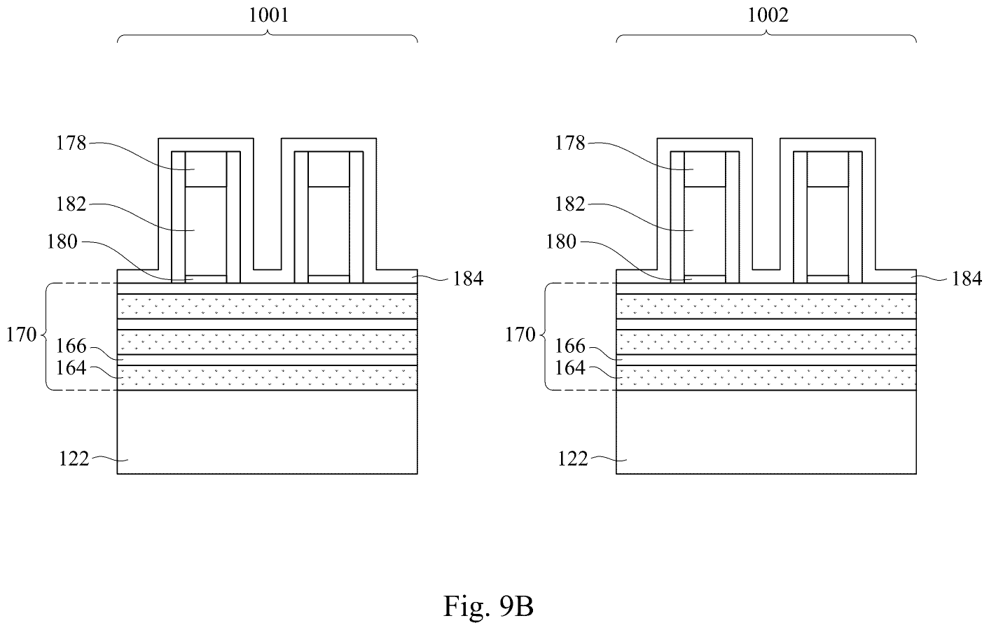

FIGS. 4 through 7, 8A, 18A, 19A, 20A, 21A and 22A illustrate reference cross-section that extends through a gate region along a longitudinal axis of the gate region of the semiconductor device 100. FIGS. 8B, 9B, 10B, 11B, 12B, 13B, 14B, 15B, 16B, 17B, 18B, 19B, 20B, 21B, 22B and 23 illustrate reference cross-section that extends through a fin along a longitudinal axis of the fin. FIGS. 9A, 10A, 11A, 12A, 13A, 14A, 15A, 16A, 17A and 18C illustrate reference cross-section that extends through source/drain regions along the longitudinal direction of the gate region.

In FIG. 4, a substrate 122 is provided. The substrate 122 may be a semiconductor substrate as discussed previously with respect to FIGS. 2A and 2B. The substrate 122 has a first device region 1001 and a second device region 1002. The first device region 1001 is a region in which transistors T1, T1a will reside, and the second device region 1002 is a region in which transistors T2, T2a will reside. In some embodiments, the transistors T1, T1a are different from the transistors T2, T2a at least in conductivity type. For example, the first device region 1001 can be for forming p-type devices, such as PMOS transistors, e.g., p-type GAA-FETs, and the second device region 1002 can be for forming n-type devices, such as NMOS transistors, e.g., n-type GAA-FETs.

The first device region 1001 may be separated from the second device region 1002, and any number of device features (e.g., other active devices, doped regions, isolation structures, etc.) may be disposed between the first device region 1001 and the second device region 1002. Although one first device region 1001 and one second device region 1002 are illustrated, any number of first device regions 1001 and second device regions 1002 may be provided. The first device region 1001 resides in the first active region pattern 108 as discussed previously with respect to FIG. 1. The second device region 1002 resides in the second active region pattern 110 as discussed previously with respect to FIG. 1.

Further in FIG. 4, a multi-layer stack 162 is formed over the substrate 122. The multi-layer stack 162 includes alternating layers of first semiconductor layers 164 and second semiconductor layers 166. For purposes of illustration and as discussed in greater detail below, the first semiconductor layers 164 will be removed and the second semiconductor layers 166 will be patterned to form channel regions of GAA-FETs.

The multi-layer stack 162 is illustrated as including three layers of each of the first semiconductor layers 164 and the second semiconductor layers 166 for illustrative purposes. In some embodiments, the multi-layer stack 162 may include any number of the first semiconductor layers 164 and the second semiconductor layers 166. Each of the layers of the multi-layer stack 162 may be epitaxially grown using a process such as chemical vapor deposition (CVD), atomic layer deposition (ALD), vapor phase epitaxy (VPE), molecular beam epitaxy (MBE), or the like. In various embodiments, the second semiconductor layers 166 may be formed of a semiconductor material suitable for serving as channel regions of GAA-FETs, such as silicon, silicon carbon, silicon germanium, or the like.

The first semiconductor materials and the second semiconductor materials may be materials having a high-etch selectivity to one another. As such, the first semiconductor layers 164 of the first semiconductor material may be removed without significantly removing the second semiconductor layers 166 of the second semiconductor material, thereby allowing the second semiconductor layers 166 to serve as channel regions of GAA-FETs.

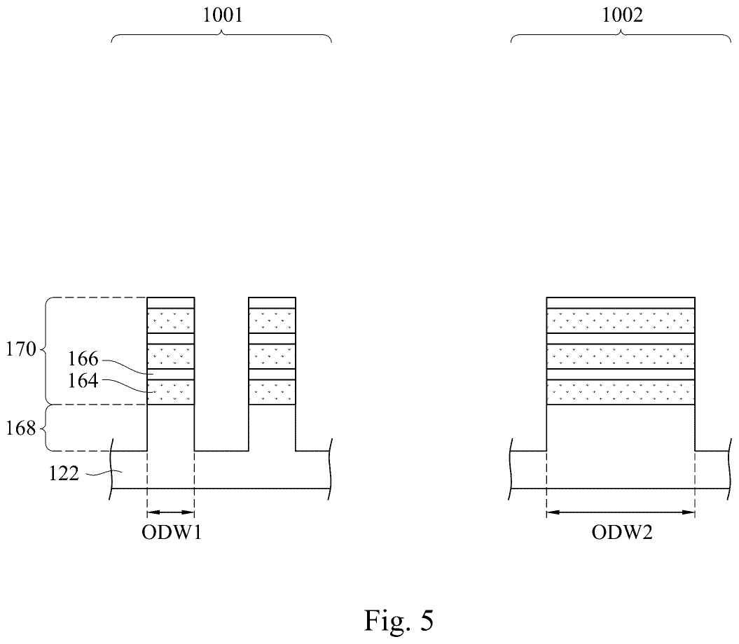

Referring now to FIG. 5, fin structures 168 are formed in the substrate 122 and nanostructures 170 are formed in the multi-layer stack 162, in accordance with some embodiments. In some embodiments, the nanostructures 170 and the fin structures 168 may be formed in the multi-layer stack 162 and the substrate 122, respectively, by etching trenches in the multi-layer stack 162 and the substrate 122. Each fin structure 168 and overlying nanostructures 170 can be collectively referred to as a fin extending from the substrate 122. The etching may be any acceptable etch process, such as a reactive ion etch (RIE), neutral beam etch (NBE), the like, or a combination thereof. The etching may be anisotropic. Forming the nanostructures 170 by etching the multi-layer stack 162 may further define first nanostructures 164 from the first semiconductor layers 164 and define second nanostructures 166 from the second semiconductor layers 166. The first nanostructures 164 and the second nanostructures 166 may further be collectively referred to as nanostructures 170. In some embodiments, the fin structure 168, the first nanostructure 164 and the second nanostructure 166 in the first device region 1001 can have a width ODW1 smaller than a width ODW2 of the fin structure 168, the first nanostructure 164 and the second nanostructure 166 in the second device region 1002.

The fin structures 168 and the nanostructures 170 may be patterned by any suitable method. For example, the fin structures 168 and the nanostructures 170 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fin structures 168.

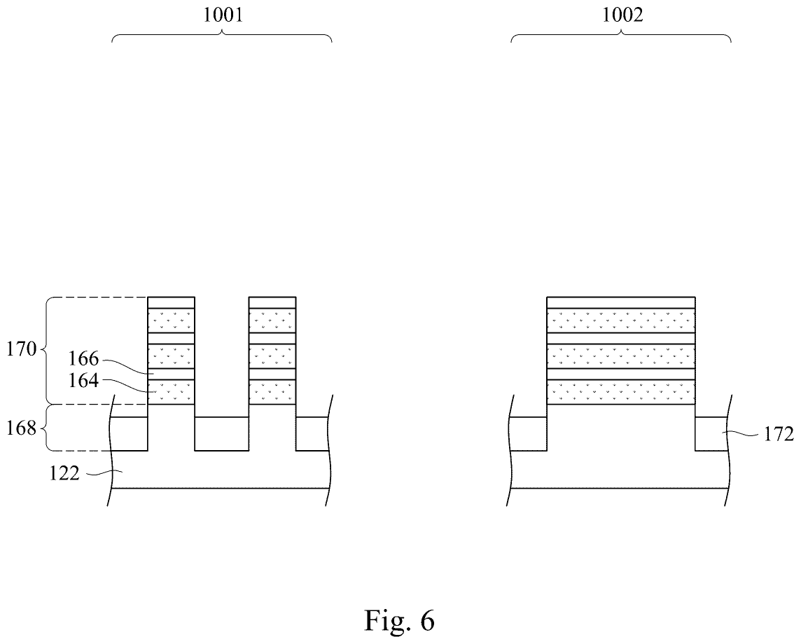

In FIG. 6, shallow trench isolation (STI) regions 172 are formed adjacent the fin structures 168. The STI regions 172 may be formed by depositing an insulation material over the substrate 122, the fin structures 168, and nanostructures 170, and between adjacent fin structures 168. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 170. Although the insulation material is illustrated as a single layer, some embodiments may utilize multiple layers. For example, in some embodiments a liner (not separately illustrated) may first be formed along a surface of the substrate 122, the fin structures 168, and the nanostructures 170. Thereafter, a fill material, such as those discussed above may be formed over the liner.

A removal process is then applied to the insulation material to remove excess insulation material over the nanostructures 170. In some embodiments, a planarization process such as a chemical mechanical polish (CMP), an etch-back process, combinations thereof, or the like may be utilized. The planarization process exposes the nanostructures 170 such that top surfaces of the nanostructures 170 and the insulation material are level after the planarization process is complete.

The insulation material is then recessed to form the STI regions 172. The insulation material is recessed such that upper portions of fin structures 168 in the first and second device regions 1001 and 1002 and protrude from between neighboring STI regions 172. Further, the top surfaces of the STI regions 172 may have a flat surface as illustrated, a convex surface, a concave surface (such as dishing), or a combination thereof. The top surfaces of the STI regions 172 may be formed flat, convex, and/or concave by an appropriate etch. The STI regions 172 may be recessed using an acceptable etching process, such as one that is selective to the material of the insulation material (e.g., etches the material of the insulation material at a faster rate than the material of the fin structures 168 and the nanostructures 170). For example, an oxide removal using, for example, dilute hydrofluoric (dHF) acid may be used.

The process described above with respect to FIGS. 4 through 6 is just one example of how the fin structures 168 and the nanostructures 170 may be formed. In some embodiments, the fin structures 168 and/or the nanostructures 170 may be formed using a mask and an epitaxial growth process. For example, a dielectric layer can be formed over a top surface of the substrate 122, and trenches can be etched through the dielectric layer to expose the underlying substrate 122. Epitaxial structures can be epitaxially grown in the trenches, and the dielectric layer can be recessed such that the epitaxial structures protrude from the dielectric layer to form the fin structures 168 and/or the nanostructures 170. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Additionally, the first semiconductor layers (and resulting nanostructures 164) and the second semiconductor layers (and resulting nanostructures 166) are illustrated and discussed herein as comprising the same materials in the second device region 1002 and the first device region 1001 for illustrative purposes only. As such, in some embodiments one or both of the first semiconductor layers and the second semiconductor layers may be different materials or formed in a different order in the first and second device regions 1001 and 1002.

Further in FIG. 6, appropriate wells (not separately illustrated) may be formed in the fin structures 168, the nanostructures 170, and/or the STI regions 172. In some embodiments with different well types in different device regions 1001 and 1002, different implant steps for the first device region 1001 and the second device region 1002 may be achieved using a photoresist or other masks (not separately illustrated). For example, a photoresist may be formed over the fin structures 168 and the STI regions 172 in the first device region 1001 and the second device region 1002. The photoresist is patterned to expose the second device region 1002. The photoresist can be formed by using a spin-on technique and can be patterned using acceptable photolithography techniques. Once the photoresist is patterned, a first impurity (e.g., n-type impurity such as phosphorus, arsenic, antimony, or the like) implant is performed in the second device region 1002, and the photoresist may act as a mask to substantially prevent the first impurities from being implanted into the first device region 1001. After the implant, the photoresist is removed, such as by an acceptable ashing process.

Following or prior to the implanting of the second device region 1002, a photoresist or other masks (not separately illustrated) is formed over the fin structures 168, the nanostructures 170, and the STI regions 172 in the first device region 1001 and the second device region 1002. The photoresist is then patterned to expose the first device region 1001. The photoresist can be formed by using a spin-on technique and can be patterned using acceptable photolithography techniques. Once the photoresist is patterned, a second impurity (e.g., p-type impurity such as boron, boron fluoride, indium, or the like) implant may be performed in the first device region 1001, and the photoresist may act as a mask to substantially prevent p-type impurities from being implanted into the second device region 1002. After the implant, the photoresist may be removed, such as by an acceptable ashing process.

After one or more well implants of the first device region 1001 and the second device region 1002, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

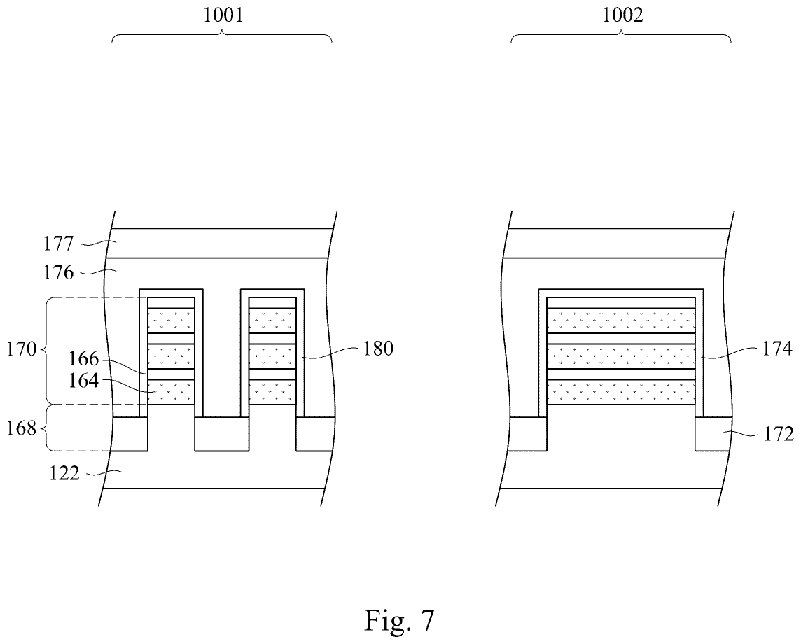

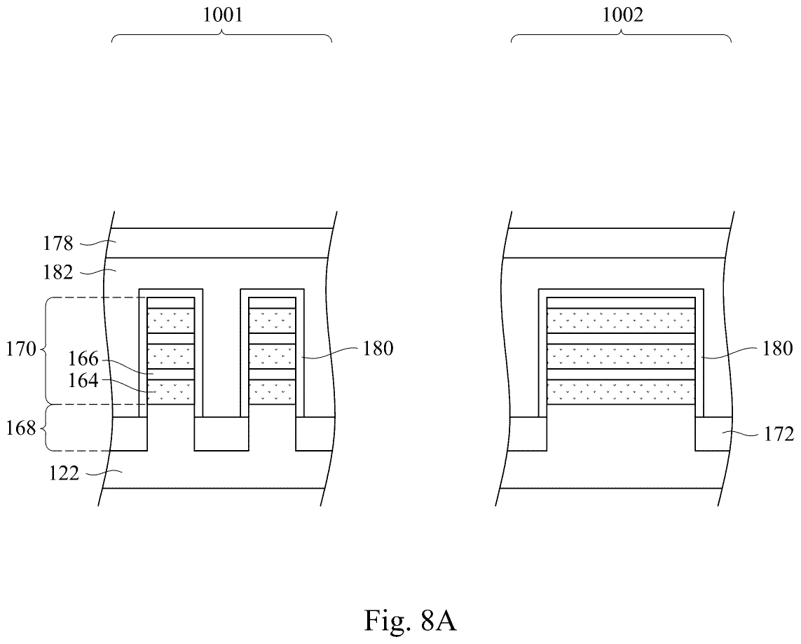

In FIG. 7, a dummy dielectric layer 174 is formed on the fin structures 168 and/or the nanostructures 170. The dummy dielectric layer 174 may be, for example, silicon oxide, silicon nitride, a combination thereof, or the like, and may be deposited or thermally grown according to acceptable techniques. A dummy gate layer 176 is formed over the dummy dielectric layer 174, and a mask layer 177 is formed over the dummy gate layer 176. The dummy gate layer 176 may be deposited over the dummy dielectric layer 174 and then planarized, such as by a CMP. The mask layer 177 may be deposited over the dummy gate layer 176. The dummy gate layer 176 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 176 may be deposited by physical vapor deposition (PVD), CVD, sputter deposition, or other techniques for depositing the selected material. The dummy gate layer 176 may be made of other materials that have a high etching selectivity from the etching of isolation regions. The mask layer 177 may include, for example, silicon nitride, silicon oxynitride, or the like. In this example, a single dummy gate layer 176 and a single mask layer 177 are formed across the first device region 1001 and the second device region 1002. It is noted that the dummy dielectric layer 174 is shown covering only the fin structures 168 and the nanostructures 170 for illustrative purposes only. In some embodiments, the dummy dielectric layer 174 may be deposited such that the dummy dielectric layer 174 covers the STI regions 172, such that the dummy dielectric layer 174 extends between the dummy gate layer 176 and the STI regions 172.

FIGS. 8A through 23 illustrate various following steps in the manufacturing of embodiment devices. In FIGS. 8A and 8B, the mask layer 177 (see FIG. 7) may be patterned using acceptable photolithography and etching techniques to form masks 178. The pattern of the masks 178 then may be transferred to the dummy gate layer 176 and to the dummy dielectric layer 174 to form dummy gates 182 and dummy gate dielectrics 180, respectively. The dummy gates 182 cover respective channel regions of the fin structures 168. The pattern of the masks 178 may be used to physically separate each of the dummy gates 182 from adjacent dummy gates 182. The dummy gates 182 may also have a lengthwise direction substantially perpendicular to the lengthwise direction of respective fin structures 168.

In FIGS. 9A and 9B, a spacer layer 184 is formed over the structures illustrated in FIGS. 8A and 8B, respectively. The spacer layer 184 will be subsequently patterned to act as spacers for forming self-aligned source/drain regions. In FIGS. 9A and 9B, the spacer layer 184 is formed on top surfaces of the STI regions 172; top surfaces and sidewalls of the fin structures 168, the nanostructures 170, and the masks 178; and sidewalls of the dummy gates 182 and the dummy gate dielectric 180. The spacer layer 184 is formed by atomic layer deposition (ALD), for example, thermal atomic layer deposition or plasma enhanced atomic layer deposition.

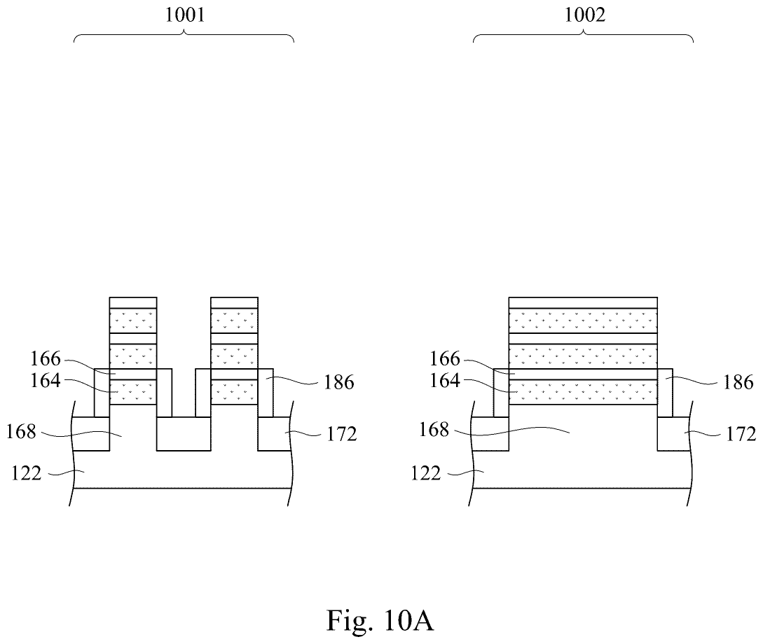

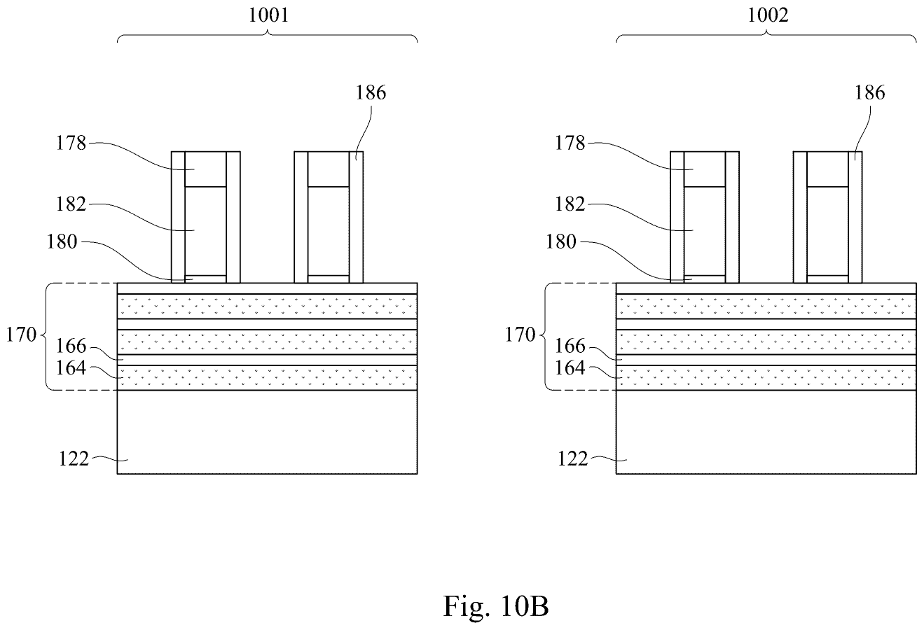

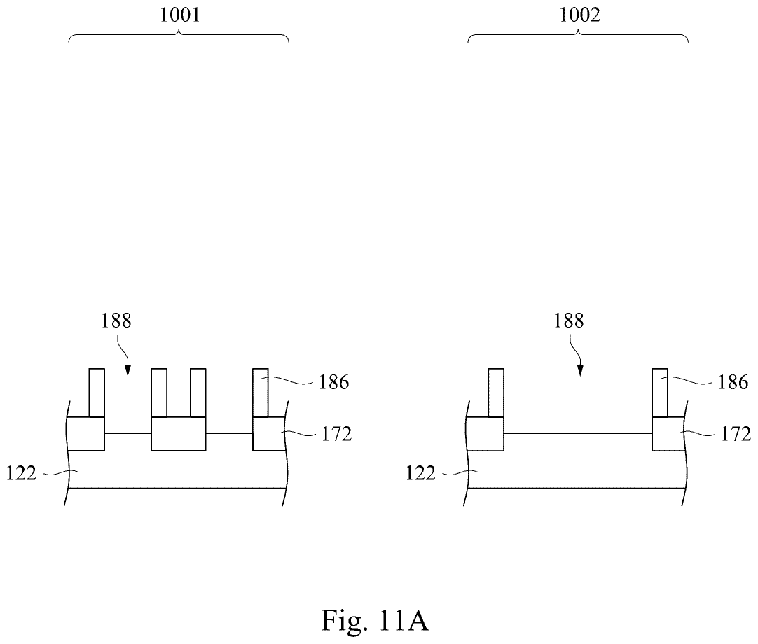

In FIGS. 10A and 10B, the spacer layer 184 is etched to form spacers 186 on opposite sidewalls of the masks 178, dummy gates 182 and dummy gate dielectrics 180. As will be discussed in greater detail below, the spacers 186 act to self-align subsequently formed source drain regions, as well as to protect sidewalls of the fin structures 168 and/or nanostructure 170 during subsequent processing. The spacer layer 184 may be etched using a suitable etching process, such as an isotropic etching process (e.g., a wet etching process), an anisotropic etching process (e.g., a dry etching process), or the like.

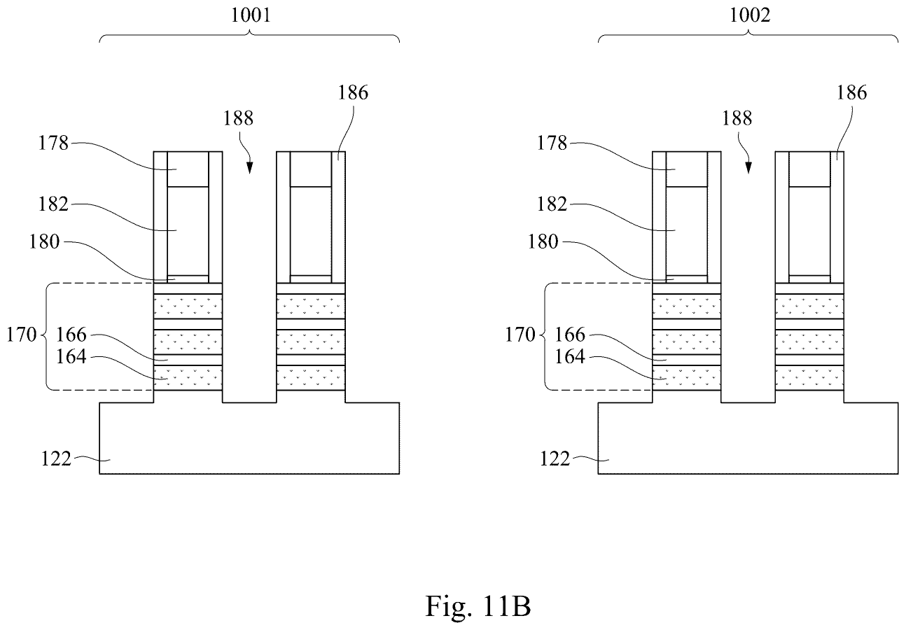

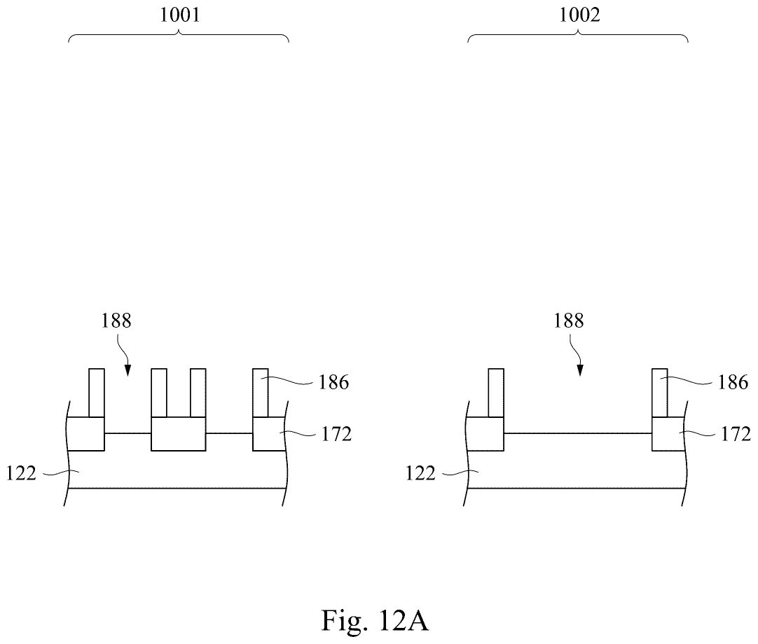

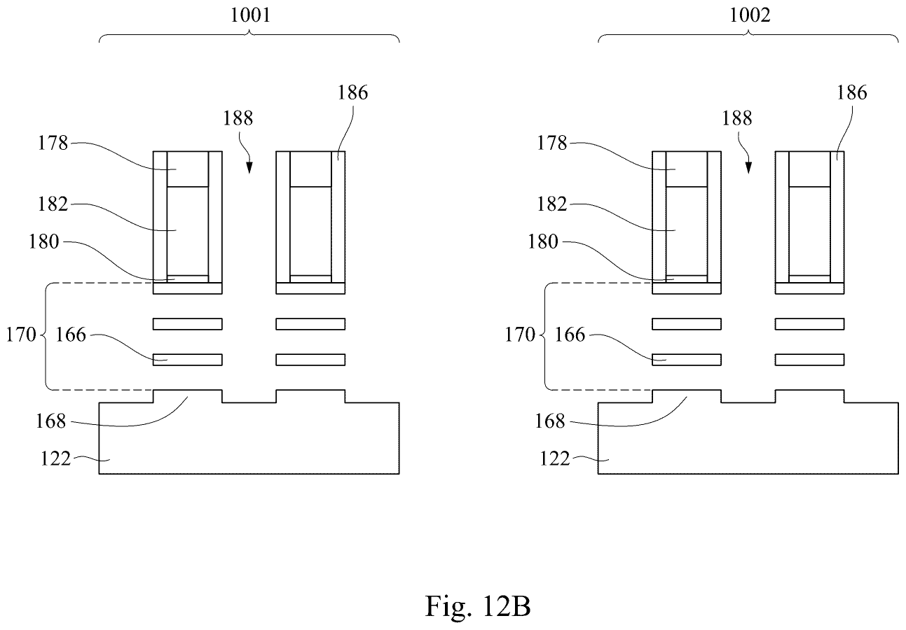

In FIGS. 11A and 11B, source/drain recesses 188 are formed in the fin structures 168, the nanostructures 170, and the substrate 122, in accordance with some embodiments. Epitaxial source/drain regions will be subsequently formed in the source/drain recesses 188. The source/drain recesses 188 may extend through the first nanostructures 164 and the second nanostructures 166, and into the substrate 122. As illustrated in FIG. 12A, bottom surfaces of the source/drain recesses 188 may be lower than top surfaces of the STI regions 58, as an example. In some other embodiments, the fin structures 168 may be etched such that bottom surfaces of the source/drain recesses 188 are disposed above or level with the top surfaces of the STI regions 172. The source/drain recesses 188 may be formed by etching the fin structures 168, the nanostructures 170, and the substrate 122 using anisotropic etching processes, such as RIE, NBE, or the like. The spacers 186 and the masks 178 mask portions of the fin structures 168, the nanostructures 170, and the substrate 122 during the etching processes used to form the source/drain recesses 188. A single etch process or multiple etch processes may be used to etch each layer of the nanostructures 170 and/or the fin structures 168. Timed etch processes may be used to stop the etching of the source/drain recesses 188 after the source/drain recesses 188 reach a target depth.

In FIGS. 12A and 12B, the first nanostructures 164 may be removed from both of the first device region 1001 and the second device region 1002 by an etching process. The etching process may be a dry etching process. The etching process may utilize NF₃, Ar, He, the like, or a combination thereof. The etching process selectively removes the silicon germanium of the first nanostructures 164 in both the first device region 1001 and the second device region 1002 while leaving portions of the silicon of the second nanostructures 166 intact in both the first device region 1001 and the second device region 1002.

Following the removal of the first nanostructures 164 in the first device region 1001 and the second device region 1002, an oxide film (not separately illustrated) may be deposited or formed over exposed surfaces of the second nanostructures 166 in the first device region 1001 and the second device region 1002 and exposed surfaces of the fin structures 168 in the first device region 1001 and the second device region 1002. The oxide film may be deposited or formed by such methods as atomic layer deposition, oxidation, or the like. However, any suitable deposition process may be used.

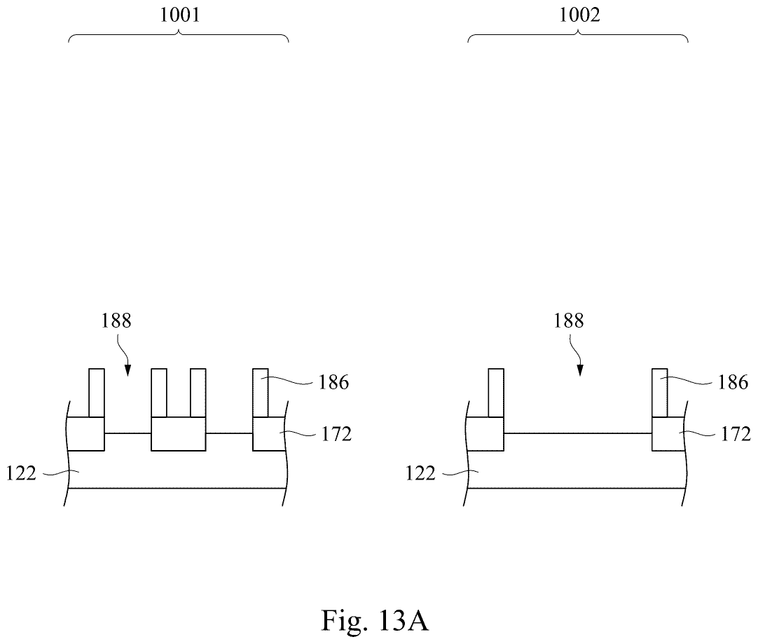

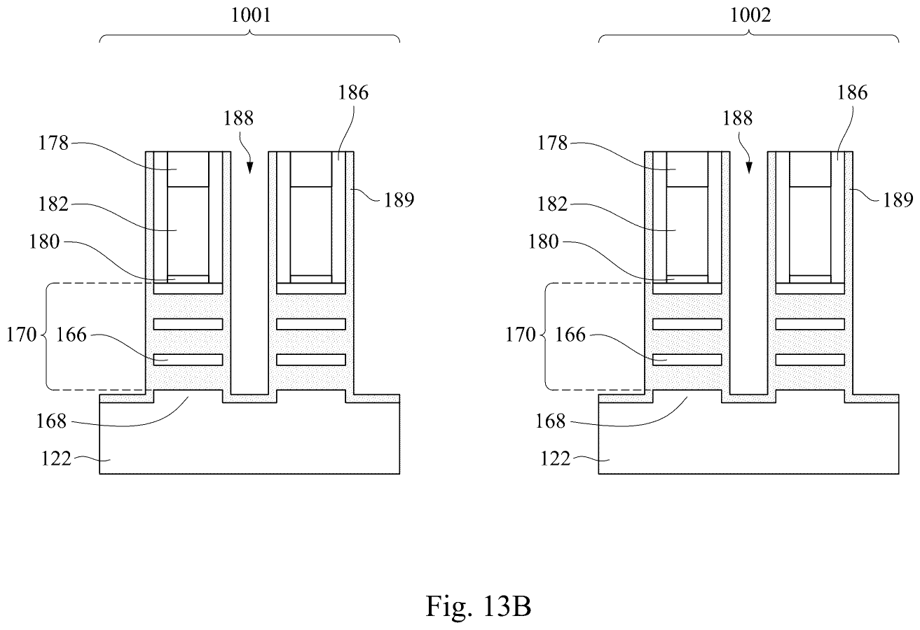

In FIGS. 13A and 13B, a deposition process is utilized to deposit an interposer material 189 over the exposed surfaces of the fin structures 168 in the first device region 1001 and the second device region 1002, the exposed surfaces of the second nanostructures 166 in the first device region 1001 and the second device region 1002 and on sidewalls of the spacers 186 in the first device region 1001 and the second device region 1002. In some embodiments, the interposer material 189 fills the gap distance between the fin structures 168 and the second nanostructure 166 in the first device region 1001 and the second device region 1002 and between the individual second nanostructures 166 in the first device region 1001 and in the second device region 1002.

In some embodiments, the deposition process is a deposition process that can fill the regions between the second nanostructures 166, such as a FCVD process, used to deposit the interposer material 189 utilizing various precursors and plasma sources. The various precursors may be applied with the facilitation of a carrier gas or a diluent. Following the deposition process (and any additional subsequent treatment processes discussed in greater detail later), the interposer material 189 may include silicon oxide, silicon nitride, silicon oxynitride, the like, or a combination thereof.

Following the deposition process, the interposer material 189 may optionally be subjected to a post-deposition curing. In an embodiment, the post-deposition curing creates a densified film (not separately illustrated) in the interposer material 189. Any suitable curing process such as a thermal curing process, ultraviolet (UV) curing process, the like or a combination thereof, may be utilized.

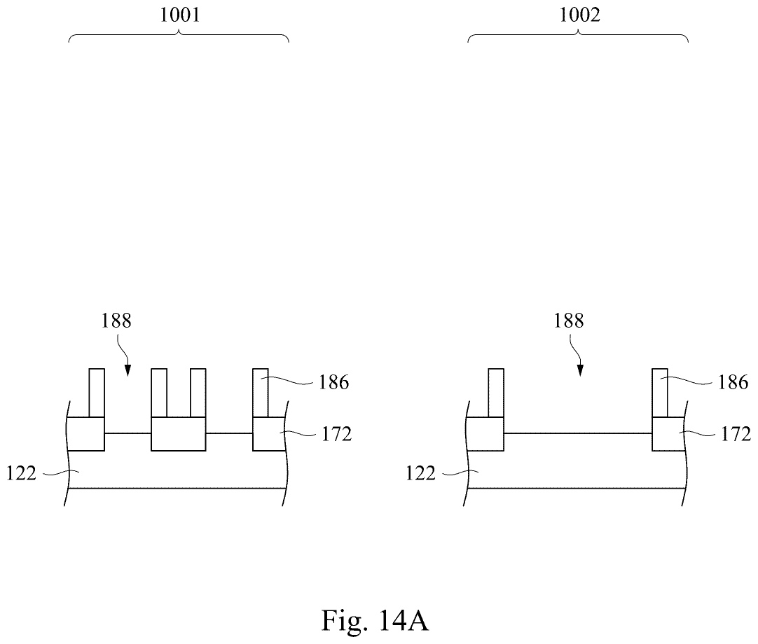

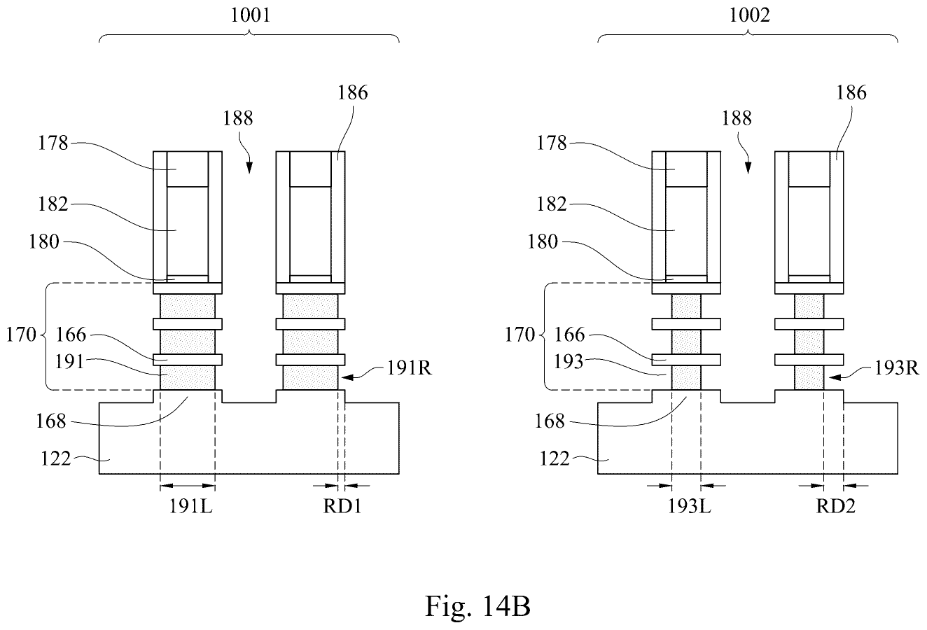

In FIGS. 14A and 14B, the interposer material 189 is subjected to an etching process, forming a first interposer 191 in the first device region 1001 and a second interposer 193 in the second device region 1002. The etching process removes portions of the interposer material 189 over the exposed surfaces of the fin structure 168 and over the spacers 186, forming interposer recesses 191R, 193R in between the second nanostructures 164. The interposer recesses 191R may have a first recess depth RD1. The interposer recesses 193R may have a second recess depth RD2. The first interposer 191 and the second interposer 193 can be referred to as disposable oxide interposer (DOI), which would be replaced with a subsequently formed metal gate structure. In the loading effect, critical dimensions (CDs) of the first interposer 191 and the second interposer 193 are in negative relationship with the width of the first nanostructure 164 since a lateral etch amount of the first nanostructure 164 in the first device region 1001 can be less than a lateral etch amount of the first nanostructure 164 in the second device region 1002. That is, due to the loading effect, the first recess depth RD1 can be smaller than the second recess depth RD2 since the first device region 1001 has the first nanostructure 164 with the width ODW1 smaller than the width ODW2 of the first nanostructure 164 of the second device region 1002. Therefore, the first interposer 191 in the first device region 1001 can have a length 191L greater than a length 193L of the second interposer 193 in the second device region 1002. As will be discussed in greater detail below, the first interposer 191 in the first device region 1001 and second interposer 193 in the second device region 1002 will be replaced with corresponding gate structures. The length 191L of the first interposer 191 and the length 193L of the second interposer 193 can control a length of the subsequently formed metal gate structure.

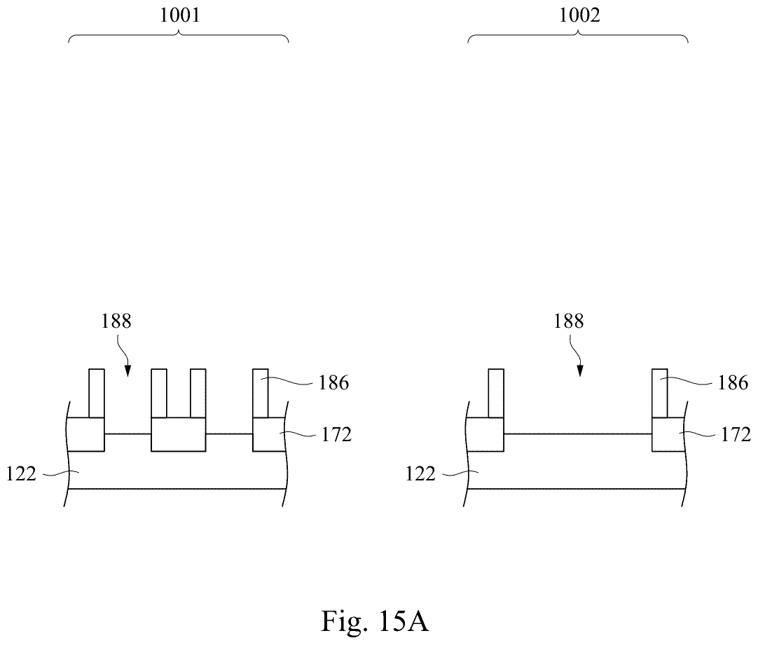

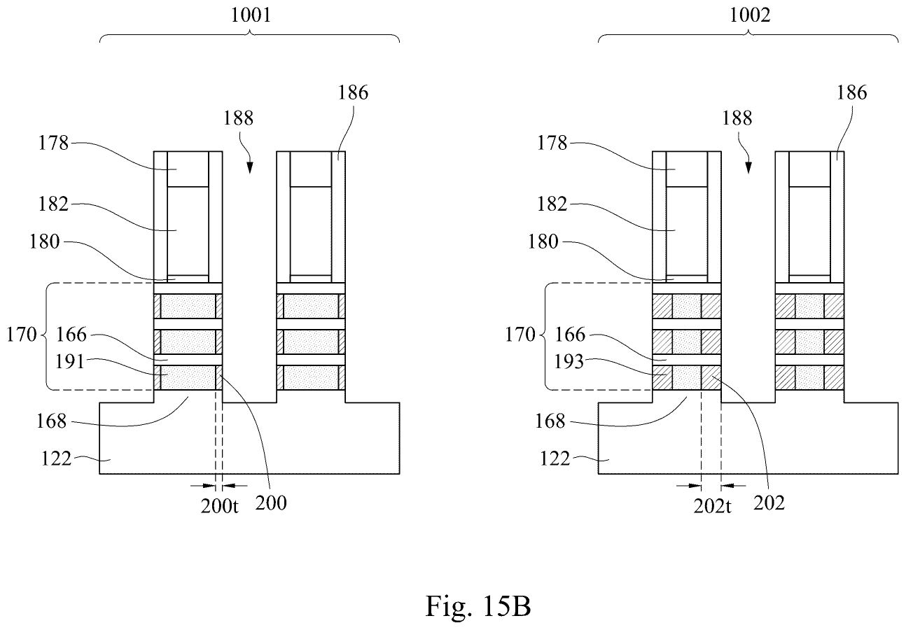

In FIGS. 15A-15B, first and second inner spacers 200, 202 are formed in the interposer recesses 191R, 193R, respectively. The first and second inner spacers 200, 202 may be formed by depositing an inner spacer layer (not separately illustrated) over the structures illustrated in FIGS. 14A and 14B. The inner spacer layer may then be anisotropically etched to form the first and second inner spacers 200, 202, such as RIE, NBE, or the like. Due to the first recess depth RD1 in the first device region 1001 being different from the second recess depth RD2 in the second device region 1002, the first inner spacers 200 in the first device region 1001 can have a first thickness 200t different from a second thickness 202t of the second inner spacers 202 in the second device region 1002. For example, the first thickness 200t can be smaller than the second thickness 202t.

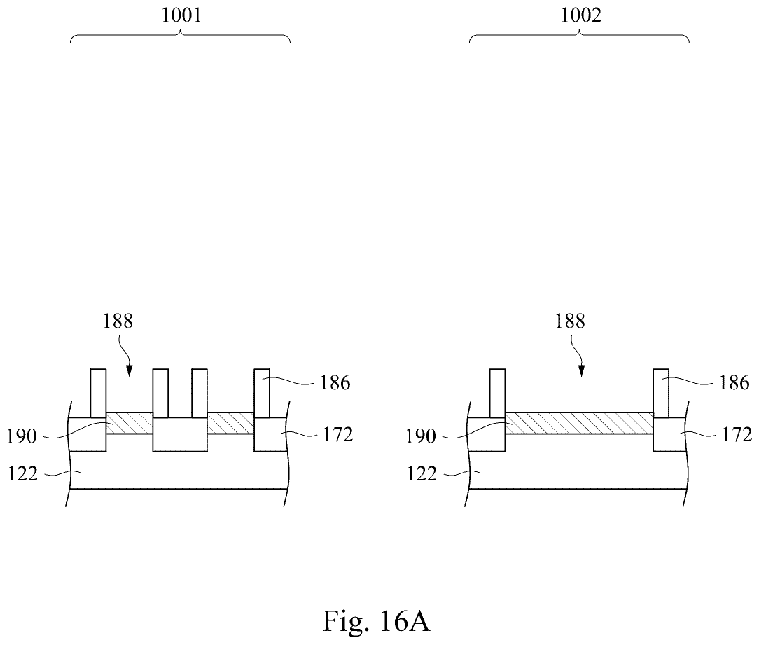

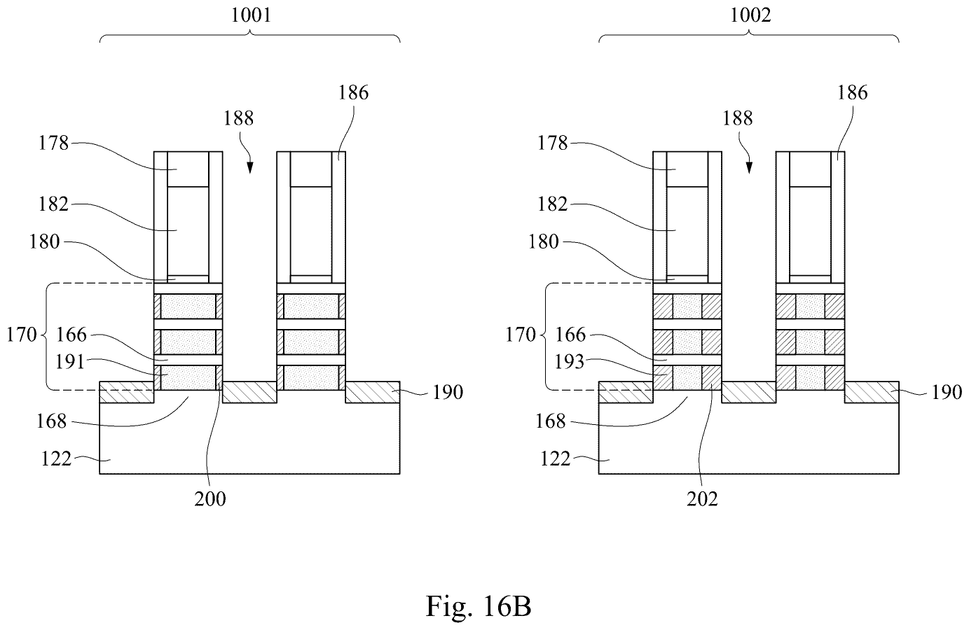

In FIGS. 16A and 16B, an insulator layer 190 is formed in the source/drain recesses 188. The insulator layer 190 formed in the source/drain recesses 188 can reduce the leakage current and can reduce the capacitance of the semiconductor device 100. The insulator layer 190 may be formed of a dielectric material, and may be deposited by any suitable method, such as PVD, CVD, plasma-enhanced CVD (PECVD), or FCVD. Dielectric materials of the insulator layer 190 may include silicon oxide, silicon nitride, hafnium oxide, the like, or a combination thereof. Other insulation materials formed by any acceptable process may be used.

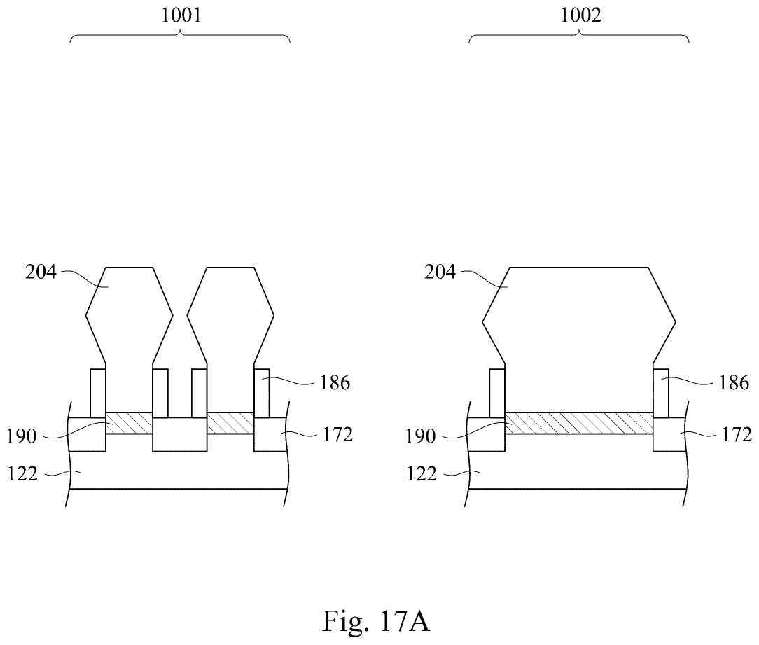

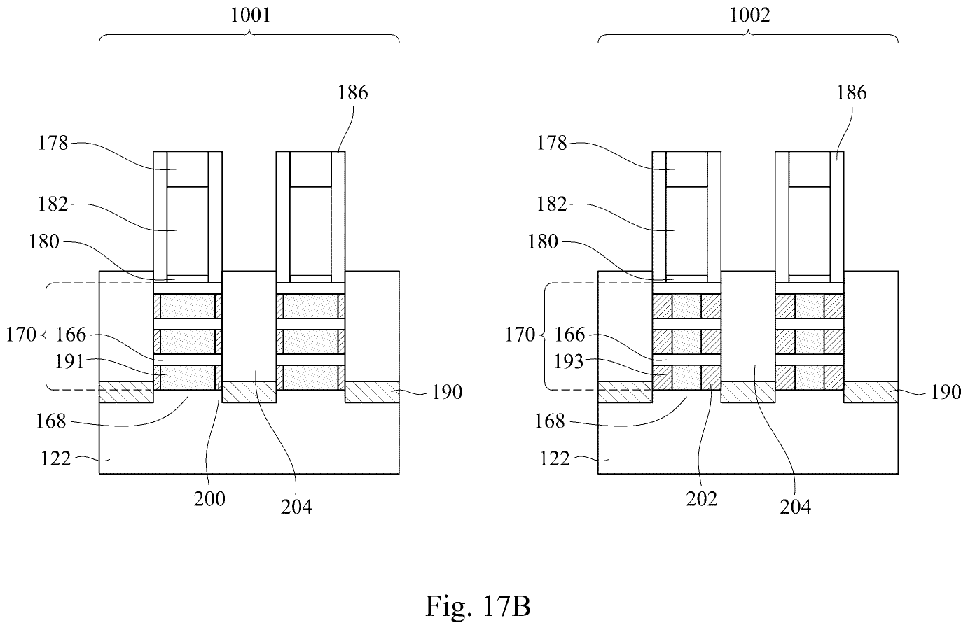

In FIGS. 17A-17B, epitaxial source/drain regions 204 are formed in the source/drain recesses 188 (see FIGS. 16A-16B). In some embodiments, the epitaxial source/drain regions 204 may exert stress on the second nanostructures 166, thereby improving device performance. As illustrated in FIG. 17B, the epitaxial source/drain regions 204 are formed in the source/drain recesses 188 such that each dummy gate 182 is disposed between respective neighboring pairs of the epitaxial source/drain regions 204. In some embodiments, the spacers 186 are used to separate the epitaxial source/drain regions 204 from the dummy gates 182 and the first, second inner spacers 200, 202 are used to separate the epitaxial source/drain regions 204 from the first interposer 191 and the second interposer 193 by an appropriate lateral distance so that the epitaxial source/drain regions 204 do not short out with subsequently formed gates of the resulting GAA-FETs.

In some embodiments, the epitaxial source/drain regions 204 may include any acceptable material appropriate for n-type GAA-FETs. For example, if the second nanostructures 166 are silicon, the epitaxial source/drain regions 204 may include materials exerting a tensile strain on the second nanostructures 166, such as silicon carbide, phosphorous doped silicon carbide, silicon phosphide, or the like. In some embodiments, the epitaxial source/drain regions 204 may include any acceptable material appropriate for p-type GAA-FETs. For example, if the second nanostructures 166 are silicon, the epitaxial source/drain regions 204 may comprise materials exerting a compressive strain on the second nanostructures 166, such as silicon germanium, boron doped silicon germanium, germanium, germanium tin, or the like.

The epitaxial source/drain regions 204 may be implanted with dopants to form source/drain regions, followed by an anneal. The n-type and/or p-type impurities for source/drain regions may be any of the impurities previously discussed. In some embodiments, the epitaxial source/drain regions 204 may be in situ doped during growth.

In some embodiments, adjacent epitaxial source/drain regions 204 remain separated after the epitaxy process is completed, as illustrated by FIG. 17A. In some other embodiments, these facets cause adjacent epitaxial source/drain regions 204 to merge. In the embodiments illustrated in FIG. 17A, the spacers 186 may be formed to a top surface of the STI regions 172 thereby blocking the lateral epitaxial growth. In some other embodiments, the spacers 186 may cover portions of the sidewalls of the nanostructures 170 further blocking the epitaxial growth. In some other embodiments, the spacer etch used to form the spacers 186 may be adjusted to remove the spacer material to allow the epitaxially grown region to extend to the surface of the STI region 172.

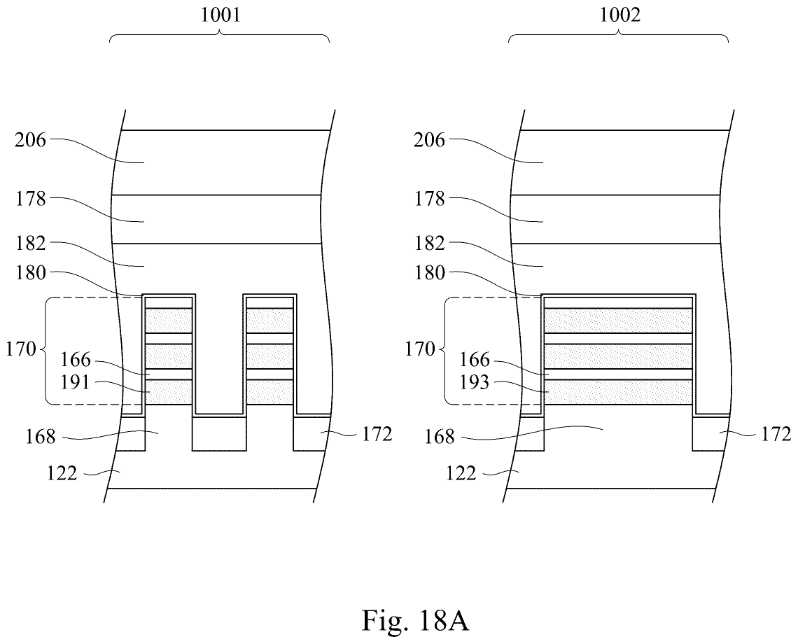

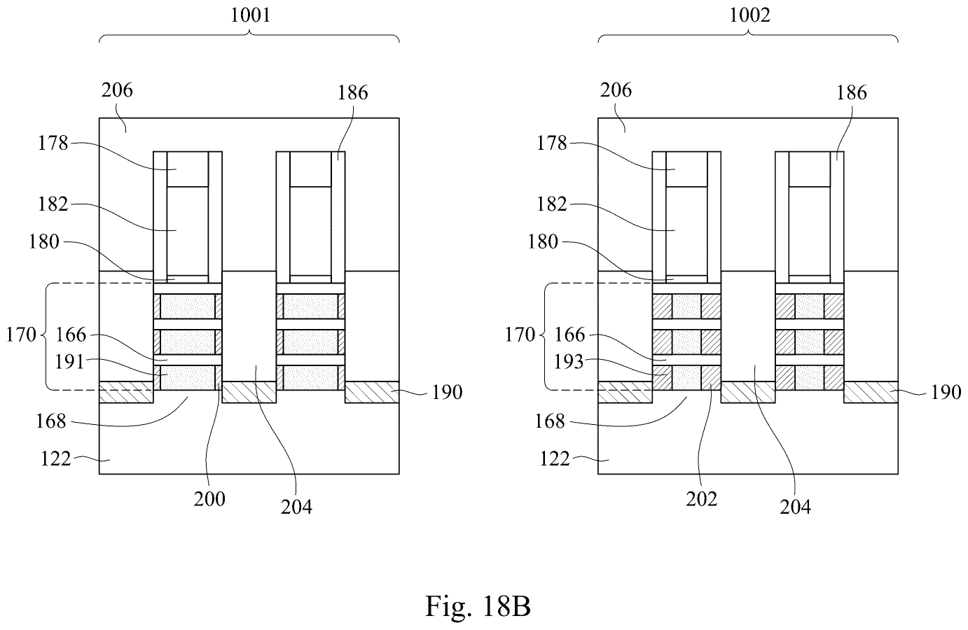

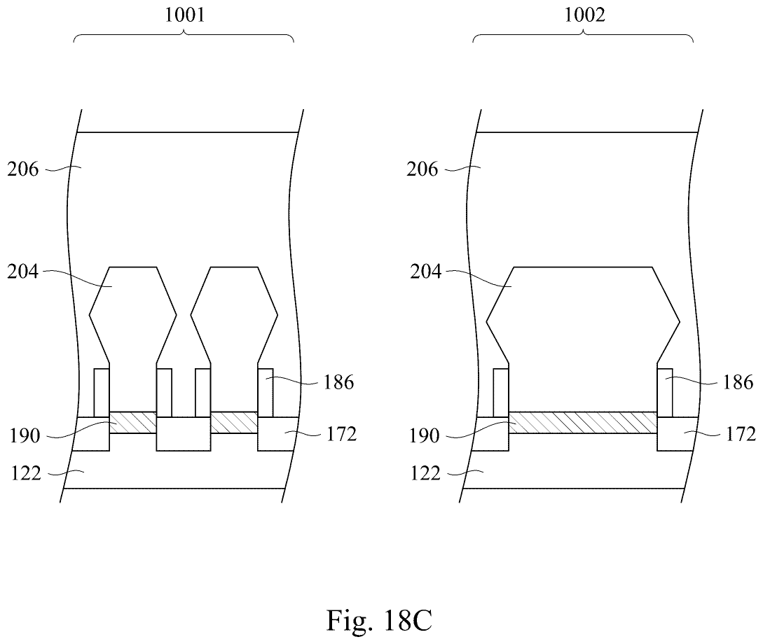

In FIGS. 18A-18C, a first interlayer dielectric (ILD) layer 206 is deposited over the structure illustrated in FIGS. 17A-17B. The first ILD layer 236 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) (not shown) is disposed between the first ILD layer 206 and the epitaxial source/drain regions 204, the masks 178, and the spacers 186. The CESL may comprise a dielectric material, such as, silicon nitride, silicon oxide, silicon oxynitride, or the like, having a different etch rate than the material of the overlying first ILD layer 206.

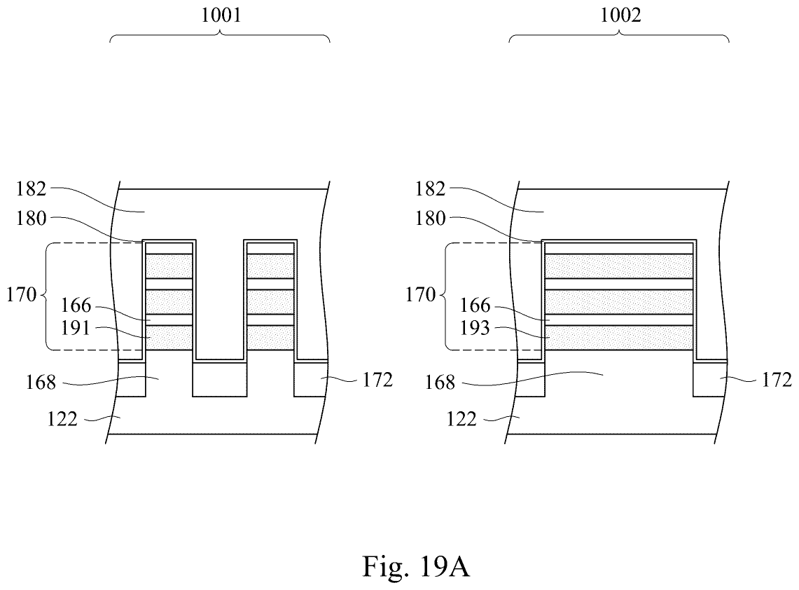

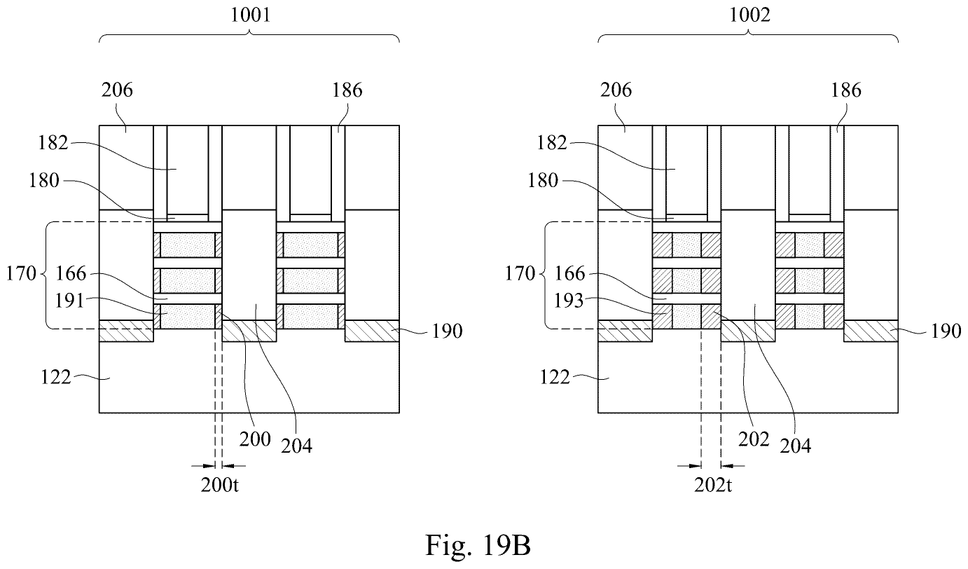

In FIGS. 19A-19B, a planarization process, such as a CMP, may be performed to level the top surface of the first ILD layer 206 with the top surfaces of the dummy gates 182 or the masks 218. The planarization process may also remove the masks 218 on the dummy gates 182, and portions of the spacers 186 along sidewalls of the masks 218. After the planarization process, top surfaces of the dummy gates 182, the spacers 186, and the first ILD layer 206 are level within process variations. Accordingly, the top surfaces of the dummy gates 182 are exposed through the first ILD layer 206. In some embodiments, the masks 218 may remain, in which case the planarization process levels the top surface of the first ILD layer 236 with top surface of the masks 218 and the spacers 186.

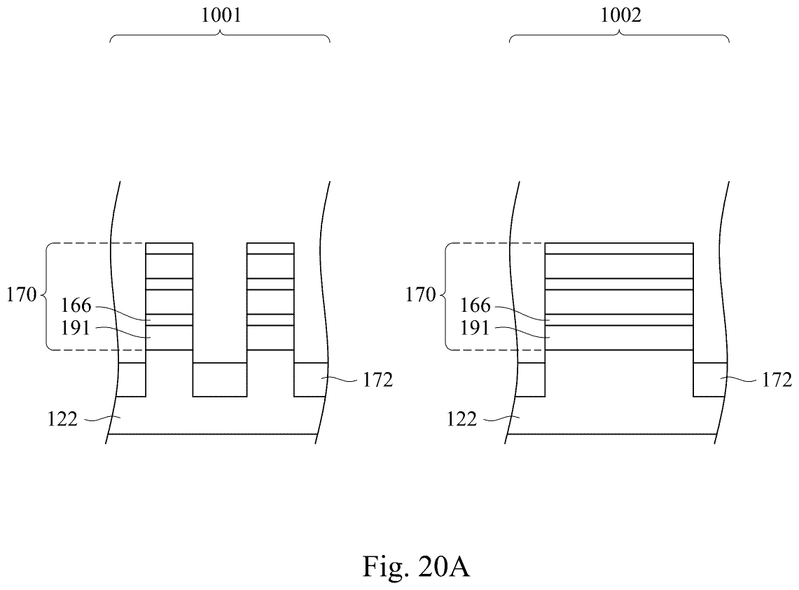

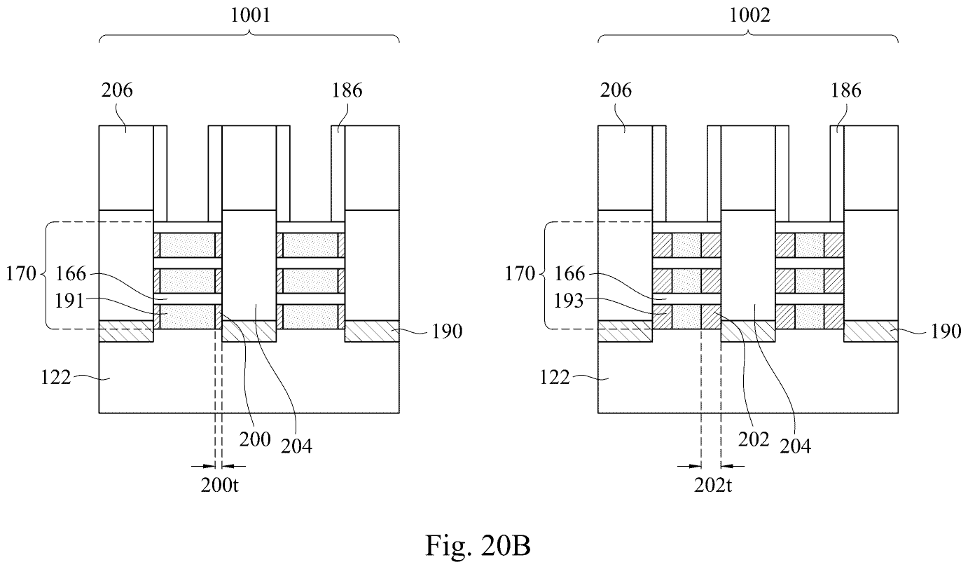

In FIGS. 20A and 20B, the dummy gates 182, and the masks 218 if present, are removed in one or more etching steps, so that gate trenches 208 are formed between corresponding spacers 186. In some embodiments, portions of the dummy gate dielectrics 180 in the gate trenches 208 are also be removed. In some embodiments, the dummy gates 182 and the dummy gate dielectrics 180 are removed by an anisotropic dry etch process. For example, the etching process may include a dry etch process using reaction gas(es) that selectively etch the dummy gates 182 at a faster rate than the first ILD layer 206 or the spacers 186. Each gate trench 208 exposes and/or overlies portions of nanostructures 170, which act as channel regions in subsequently completed GAA-FETs. The nanostructures 170 which act as the channel regions are disposed between neighboring pairs of the epitaxial source/drain regions 204. During the removal, the dummy gate dielectrics 180 may be used as etch stop layers when the dummy gates 182 are etched. The dummy gate dielectrics 180 may then be removed after the removal of the dummy gates 182.

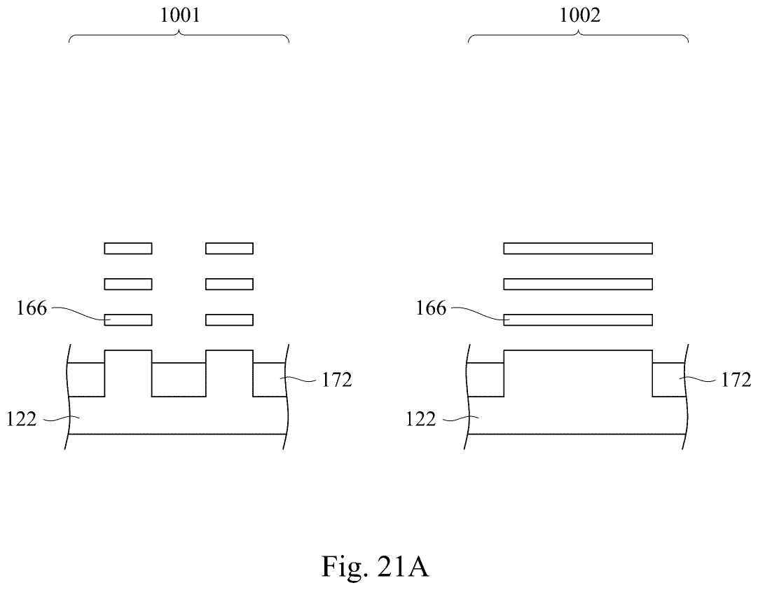

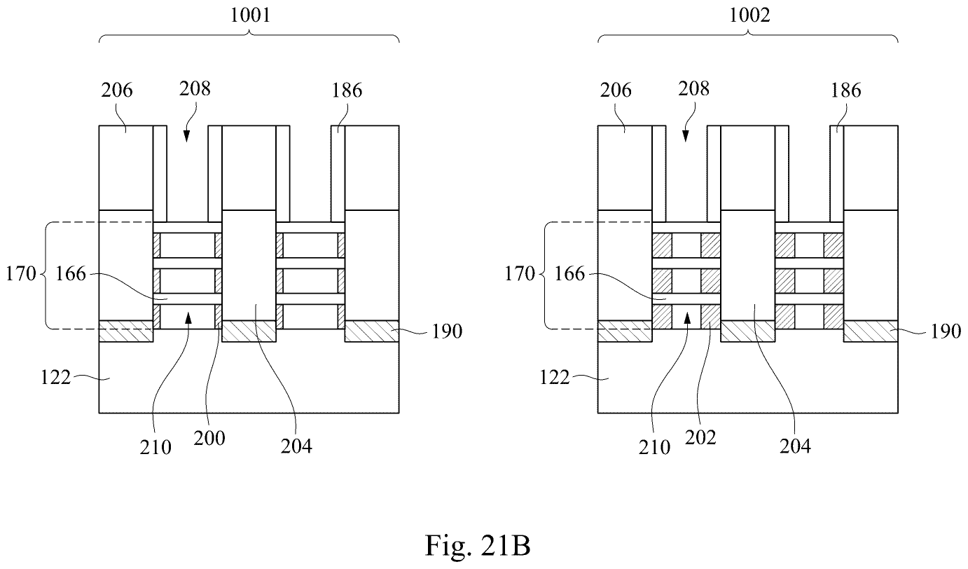

In FIGS. 21A and 21B, the first interposer 191 and the second interposer 193 in the gate trenches 208 are removed by an isotropic etching process such as wet etching or the like using etchants which are selective to the materials of the first interposer 191 and the second interposer 193. The etching process may be a cyclic dry etching process. The etching process may utilize hydrogen fluoride (HF) gas, ammonia (NH₃) gas, the like, or a combination thereof. However, any suitable etching process or etching parameters may be utilized to remove the first interposer 191 and the second interposer 193. Spaces are formed between the second nanostructures 166 (also referred to as sheet-sheet spaces if the nanostructures 164 are nanosheets). This step can be referred to as a channel release process. As illustrated in FIGS. 21A and 21B, gaps 210 (empty spaces) are formed between the second nanostructures 166. At this interim processing step, the gaps 210 between second nanostructures 166 may be filled with ambient environment conditions (e.g., air, nitrogen, etc). In some embodiments, the second nanostructures 166 can be referred to as nanosheets, nanowires, nanoslabs, nanorings having nano-scale size (e.g., a few nanometers), depending on their geometry. For example, in some embodiments, the second nanostructures 166 may be trimmed to have a substantial rounded shape (i.e., cylindrical) due to the selective etching process for completely removing the first nanostructures 164. In that case, the resultant second nanostructures 166 can be called nanowires.

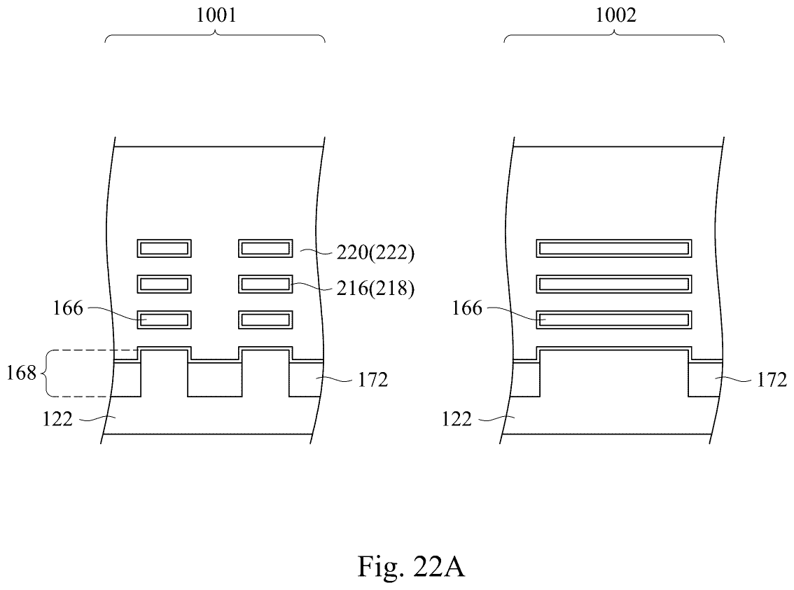

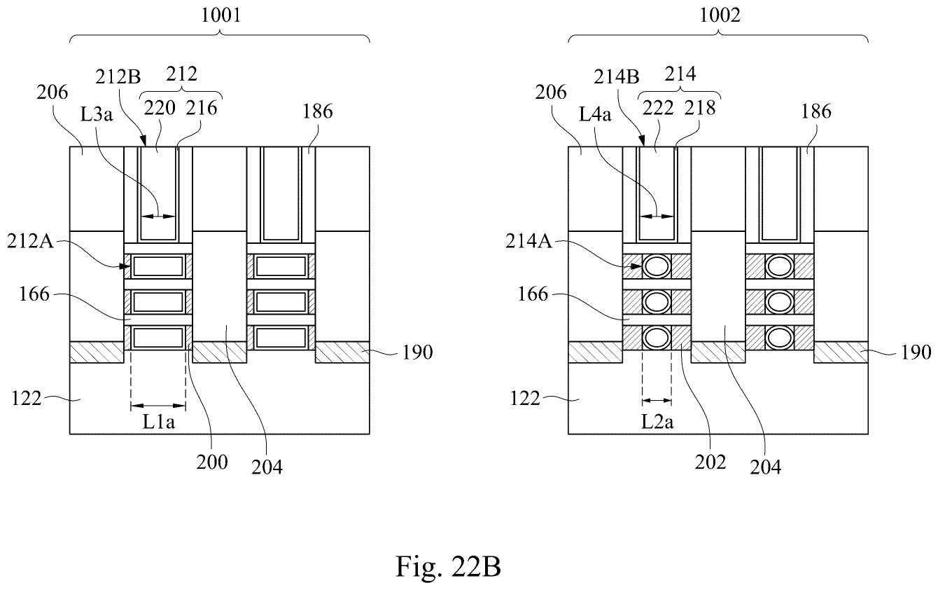

Next, in FIGS. 22A and 22B, high-k/metal gate structures 212, 214 are formed. For example, gate dielectric layers 216, 218 are formed (e.g., conformally) in the gate trenches 208 and in the gaps 210. In the first device region 1001, the gate dielectric layer 216 wraps around the second nanostructures 166, lines sidewalls of the first inner spacers 200 and sidewalls of the spacers 186, and extends along the upper surface of the fin structures 168. In accordance with some embodiments, the gate dielectric layer 216 comprises silicon oxide, silicon nitride, or multilayers thereof. In some embodiments, the gate dielectric layer 216 includes a high-k dielectric material, and in these embodiments, the gate dielectric layer 216 may have a dielectric constant greater than about 7.0, and may include a metal oxide or a silicate of Hf, Al, Zr, La, Mg, Ba, Ti, or Pb, or combinations thereof. The formation methods of the gate dielectric layer 216 may include Molecular-Beam Deposition (MBD), ALD, PECVD, and the like. In the second device region 1002, the gate dielectric layer 218 wraps around the second nanostructures 166, lines sidewalls of the second inner spacers 202 and sidewalls of the spacers 186, and extends along the upper surface of the fin structures 168.

In an alternative embodiment, an interfacial layer (not shown) is deposited between the gate dielectric layers 216, 218 and the second nanostructures 166 and is formed of silicon oxide or silicon oxynitride grown by a thermal oxidation process. For example, the interfacial layer can be grown by a rapid thermal oxidation (RTO) process or by an annealing process using oxygen.

Next, a gate electrode material (e.g., an electrically conductive material) is formed in the gate trenches 208 and in the gaps 210 to form the gate electrodes 220, 222. The gate electrodes 220 fill the remaining portions of the gate trenches 208 and in the gaps 210. For example, the gate electrodes 220 include one or more work function layers and a fill metal layer (not separately illustrated). A CMP is then performed on the gate electrodes 220, 222 and the gate dielectric layers 216, 218 until the first ILD layer 206 is exposed, resulting in the gate electrodes 220, 222 and the gate dielectric layers 216, 218 and the first ILD layer 206 having substantially level top surfaces.

The one or more work function layers can provide a suitable work function for the high-k/metal gate structures. For an n-type GAA FET, the one or more work function layers may include one or more n-type work function metals (N-metal). The n-type work function metals may exemplarily include, but are not limited to, titanium aluminide (TiAl), titanium aluminium nitride (TiAlN), carbo-nitride tantalum (TaCN), hafnium (Hf), zirconium (Zr), titanium (Ti), tantalum (Ta), aluminum (Al), metal carbides (e.g., hafnium carbide (HfC), zirconium carbide (ZrC), titanium carbide (TiC), aluminum carbide (AlC)), aluminides, and/or other suitable materials. On the other hand, for a p-type GAA FET, the one or more work function layers may include one or more p-type work function metals (P-metal). The p-type work function metals may exemplarily include, but are not limited to, titanium nitride (TiN), tungsten nitride (WN), tungsten (W), ruthenium (Ru), palladium (Pd), platinum (Pt), cobalt (Co), nickel (Ni), conductive metal oxides, and/or other suitable materials.

In some embodiments, the fill metal layer may exemplarily include, but are not limited to, tungsten, aluminum, copper, nickel, cobalt, titanium, tantalum, titanium nitride, tantalum nitride, nickel silicide, cobalt silicide, TaC, TaSiN, TaCN, TiAl, TiAlN, or other suitable materials. As discussed previously with regard to FIGS. 2A and 2B, the high-k/metal gate structures 212 can include inner gates 212A between two adjacent second nanostructures 166 and an outer gate 212B above the topmost one of the second nanostructures 166. The high-k/metal gate structures 214 can include inner gates 214A between two adjacent semiconductor layers 166 and an outer gate 214B above the second nanostructures 166. In the first device region 1001, a length L1a of the inner gates 212A is greater than a length L3a of the outer gate 212B. In the second device region 1002, the length L2a of the inner gates 214A is greater than a length L4a of the outer gate 214B.

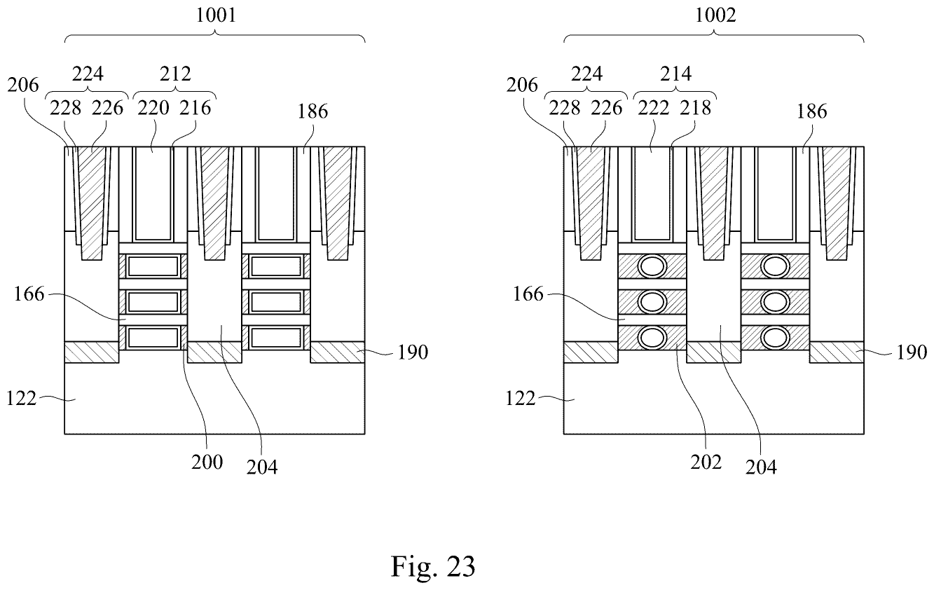

Reference is made to FIG. 23. Contacts 224 are formed in contact with the epitaxial source/drain regions 204. Formation of the contacts 224 may include, forming contact openings (holes) in the first ILD layer 206 so as to at least partially expose the upper surfaces of the epitaxial source/drain regions 204. The contact openings are formed by using one or more lithography operations and one or more etching operations. A photo resist pattern and/or a hard mask pattern is used in the etching operations.

In some embodiments, the contact openings have a tapered shape having a top width wider than a bottom width. After the contact openings are formed, an insulating liner layer 228 is conformally formed in the contact openings and the upper surface of the first ILD layer 206. The insulating liner layer 228 may be formed by low pressure CVD (LPCVD), physical vapor deposition (PVD) including sputtering, or atomic layer deposition (ALD).

The insulating liner layer 228 is made of one or more layers of SiN, SiON, SiCN, SiC, SiOCN or SiOC, or any other suitable dielectric material. In some embodiments, the insulating liner layer 228 is made of a dielectric material different from the first ILD layer 206. Other dielectric material, such as AlO, AlON or AN may be used as the insulating liner layer 228. In one embodiment, SiN is used.

As shown in FIG. 23, since the etching of the first ILD layer 206 to form the contact openings does not fully remove the first ILD layer 206 between two gate structures 212 and between the two gate structures 214, a part of the first ILD layer 206 remains between the sidewall spacer 186 and the insulating liner layer 228.

Subsequently, upper portions of the insulating liner layer 228 in the contact openings are partially removed by using an etching operation. The insulating liner layer 228 formed on the upper surface of the first ILD layer 206 is also removed. In some embodiments, the insulating liner layer 228 formed on the upper surface of the second ILD layer 206 is fully removed. Further, the insulating liner layer 228 covering the epitaxial source/drain regions is also removed, thereby exposing the epitaxial source/drain regions 204.

Subsequently, a conductive material layer 226 is formed in the contact openings with the remaining insulating liner layers 228 and the upper surface of the first ILD layer 206. In some embodiments, the conductive material layer 226 includes a conformally formed layer of an adhesive (glue) layer and a body metal layer. The adhesive layer includes one or more layers of conductive materials. In some embodiments, the adhesive layer includes a TiN layer formed on a Ti layer. Any other suitable conductive material can be used. The thickness of each of the TiN and Ti layer is in a range from about 1 nm to about 5 nm in some embodiments. The adhesive layer can be formed by CVD, PVD, ALD, electro-plating or a combination thereof, or other suitable film forming methods. The adhesive layer is used to prevent the body metal layer from peeling off. In some embodiments, no adhesive layer is used and the body metal layer is directly formed in the contact openings.

The body metal layer is one of Co, W, Mo and Cu, or any other suitable conductive material. In one embodiment, Cu is used as the body metal layer. The body metal layer can be formed by CVD, PVD, ALD, electro-plating or a combination thereof or other suitable film forming methods.

After the conductive material layer 226 is formed, a planarization operation, such as chemical mechanical polishing (CMP) or etch-back operations, is performed, thereby so as to remove the excess materials deposited on the upper surface of the first ILD layer 206, thereby forming contacts 224, as shown in FIG. 23.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that a semiconductor device including a first OD pattern in a first device region with a small ODW can have a first interposer longer than a second interposer of the second OD pattern with a large ODW in a second device region due to loading effect such that the first inner spacer abutting the first interposer can be formed thinner than the second inner spacers abutting the second interposer. In the first device region, the first inner spacers are small such that a first metal gate crossing the first OD pattern can have a large critical dimension (CD) in between nanostructures. Another advantage is that Short channel effect (SCE) and drain-induced barrier lowering (DIBL) of the semiconductor device can be effectively controlled. Junction between a source/drain region and a nanosheet channel region can overlap even without additional process for convex push or junction push, and hence better on-current (Ion) can be achieved. Yet another advantage is that the semiconductor device can be applied to low threshold power (P_{sb}) device with reduced SCE or combined with OD jog for Design Technology Co-Optimization (DTCO).

In some embodiments, a semiconductor device includes a substrate, an isolation structure, first nanostructures, second nanostructures, a first inner spacer and a second inner spacer. The substrate comprises a first active region pattern comprising a plurality of first nanostructures and a second active region pattern comprising a plurality of second nanostructure, wherein the first active region pattern does not overlap the second active region pattern. The isolation structure surrounds the first active region pattern and the second active region pattern. The plurality of first nanostructures extend in a first direction above the first active region pattern and spaced apart in a second direction perpendicular to the first direction. The plurality of second nanostructures extend in the first direction above the second active region pattern and spaced apart in the second direction. The first inner spacer is between the two adjacent first nanostructures, wherein the first inner spacer has a first thickness along the first direction. The second inner spacer is between the two adjacent second nanostructures. The second inner spacer has a second thickness along the first direction, and the first thickness is different from the second thickness. In some embodiments, the first thickness is smaller than the second thickness. In some embodiments, a thickness difference between the first thickness and the second thickness is in a range from about 1 nm to about 2 nm. In some embodiments, the first active region pattern has a width different from a width of the second active region pattern. In some embodiments, the first active region pattern has the width smaller than the width of the second active region pattern. In some embodiments, the semiconductor device further comprises a first gate structure. The first gate structure comprises an inner gate abutting first inner spacer and an outer gate over the first nanostructures, wherein the inner gate has a length different from a length of the outer gate. In some embodiments, the inner gate has the length greater than the length of the outer gate. In some embodiments, the semiconductor device further comprises a second gate structure. The second gate structure comprises an inner gate abutting second inner spacer and an outer gate over the second nanostructures, wherein the inner gate has a length different from a length of the outer gate. In some embodiments, the inner gate has the length smaller than the length of the outer gate.

In some embodiments, a semiconductor device comprises a substrate, an isolation structure, a first transistor and a second transistor. The substrate comprises—a first active region pattern comprising a plurality of first channel layers and a second active region pattern comprising a plurality of second channel layers, wherein the first active region pattern does not overlap the second active region pattern. The isolation structure surrounds the first active region pattern and the second active region pattern. The first transistor comprises the plurality of first channel layers extending in a first direction above the first active region pattern and spaced apart in a second direction perpendicular to the first direction, and a first gate structure surrounding the first channel layers. The second transistor comprises the plurality of second channel layers extending in the first direction above the second active region pattern and spaced apart in the second direction. and a second gate structure surrounding the second channel layers, wherein the first gate structure has a length along the first direction different from a length of the second gate structure along the second direction. In some embodiments, the first active region pattern has a width different from a width of the second active region pattern. In some embodiments, the first active region pattern has the width smaller than the width of the second active region pattern. In some embodiments, the first transistor is a p-type transistor, and the second transistor is an n-type transistor. In some embodiments, the semiconductor device further comprises when viewed from a top view, a first strip structure abutting an edge of the first active region pattern, and a second strip structure abutting an edge of the second active region pattern. In some embodiments, the semiconductor device further comprises when viewed from a top view, a strip structure abutting an edge of the first active region pattern and an edge of the second active region pattern. In some embodiments, a distance between the first active region pattern and the second active region pattern equals to a minimum distance between a center of the first gate structure and a center of the second gate structure. In some embodiments, the semiconductor device further comprises a jog portion between an edge of the first active region pattern and an edge of the second active region pattern, wherein the jog portion has a trapezoid profile when viewed from a top view. In some embodiments, a distance between the first active region pattern and the second active region pattern is less than a minimum distance between a center of the first gate structure and a center of the second gate structure.

In some embodiments, a method of forming a semiconductor device comprises the following steps. A nanostructure is formed over a substrate, wherein the nanostructure comprises a plurality of alternately stacked first semiconductor layers and second semiconductor layers. A dummy gate is formed across the nanostructure. Gate spacers are formed on opposite sidewalls of the dummy gate. Sidewalls of the first semiconductor layers are etched. Inner spacers are formed abutting the sidewalls of the first semiconductor layers. The dummy gate is replaced with a metal gate, wherein the metal gate has an outer portion abutting the gate spacers and an inner portion abutting the inner spacers, and the outer portion comprises a length different from a length of the inner portion. In some embodiments, the outer portion comprises the length smaller than the length of the inner portion.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate comprising a first active region pattern comprising a plurality of first nanostructures and a second active region pattern comprising a plurality of second nanostructures, the plurality of first nanostructures extending in a first direction above the first active region pattern and spaced apart in a second direction perpendicular to the first direction, the plurality of second nanostructures extending in the first direction above the second active region pattern and spaced apart in the second direction, wherein the first active region pattern does not overlap the second active region pattern;
an isolation structure surrounding the first active region pattern and the second active region pattern;
a first inner spacer between the two adjacent first nanostructures, wherein the first inner spacer has a first thickness along the first direction; and
a second inner spacer between the two adjacent second nanostructures, wherein the second inner spacer has a second thickness along the first direction, and the first thickness is different from the second thickness.

2. The semiconductor device of claim 1, wherein the first thickness is smaller than the second thickness.

3. The semiconductor device of claim 2, wherein a thickness difference between the first thickness and the second thickness is in a range from about 1 nm to about 2 nm.

4. The semiconductor device of claim 1, wherein the first active region pattern has a width different from a width of the second active region pattern.

5. The semiconductor device of claim 4, wherein the first active region pattern has the width smaller than the width of the second active region pattern.

6. The semiconductor device of claim 1, further comprising:
a first gate structure comprising:
an inner gate abutting first inner spacer; and
an outer gate over the plurality of first nanostructures, wherein the inner gate has a length different from a length of the outer gate.

7. The semiconductor device of claim 6, wherein the inner gate has the length greater than the length of the outer gate.

8. The semiconductor device of claim 1, further comprising:
a second gate structure comprising:
an inner gate abutting second inner spacer; and
an outer gate over the plurality of second nanostructures, wherein the inner gate has a length different from a length of the outer gate.

9. The semiconductor device of claim 7, wherein the inner gate has the length smaller than the length of the outer gate.

10. A semiconductor device, comprising:
a substrate comprising a first active region pattern comprising a plurality of first channel layers and a second active region pattern comprising a plurality of second channel layers, wherein the first active region pattern does not overlap the second active region pattern;
an isolation structure surrounding the first active region pattern and the second active region pattern;
a first transistor comprising:
the plurality of first channel layers extending in a first direction above the first active region pattern and spaced apart in a second direction perpendicular to the first direction; and
a first gate structure surrounding the first channel layers;
a second transistor comprising:
the plurality of second channel layers extending in the first direction above the second active region pattern and spaced apart in the second direction; and
a second gate structure surrounding the second channel layers, wherein the first gate structure has a length along the first direction different from a length of the second gate structure along the second direction.

11. The semiconductor device of claim 10, wherein the first active region pattern has a width different from a width of the second active region pattern.

12. The semiconductor device of claim 11, wherein the first active region pattern has the width smaller than the width of the second active region pattern.

13. The semiconductor device of claim 10, wherein the first transistor is a p-type transistor, and the second transistor is an n-type transistor.

14. The semiconductor device of claim 10, further comprising:
when viewed from a top view, a first strip structure abutting an edge of the first active region pattern, and a second strip structure abutting an edge of the second active region pattern

15. The semiconductor device of claim 10, further comprising:
when viewed from a top view, a strip structure abutting an edge of the first active region pattern and an edge of the second active region pattern.

16. The semiconductor device of claim 10, wherein a distance between the first active region pattern and the second active region pattern equals to a minimum distance between a center of the first gate structure and a center of the second gate structure.

17. The semiconductor device of claim 16, further comprising:
a jog portion between an edge of the first active region pattern and an edge of the second active region pattern, wherein the jog portion has a trapezoid profile when viewed from a top view.

18. The semiconductor device of claim 10, wherein a distance between the first active region pattern and the second active region pattern is less than a minimum distance between a center of the first gate structure and a center of the second gate structure.

19. A method of forming a semiconductor device, comprising:
forming a nanostructure over a substrate, wherein the nanostructure comprises a plurality of alternately stacked first semiconductor layers and second semiconductor layers;
forming a dummy gate across the nanostructure;
forming gate spacers on opposite sidewalls of the dummy gate;
etching sidewalls of the first semiconductor layers;
forming inner spacers abutting the sidewalls of the first semiconductor layers; and
replacing the dummy gate with a metal gate, wherein the metal gate has an outer portion abutting the gate spacers and an inner portion abutting the inner spacers, and the outer portion comprises a length different from a length of the inner portion.

20. The method of claim 19, wherein the outer portion comprises the length smaller than the length of the inner portion.
